(19) United States
(12) Patent Application Publication
(10) Pub. No.: US 2008/0267239 A1
(43) Pub. Date: Oct. 30, 2008

(54) High-Index-Contrast Waveguide

(76) Inventors: Douglas Hall, South Bend, IN (US); Di Liang, Mishawaka, IN (US)

Correspondence Address: HANLEY, FLIGHT & ZIMMERMAN, LLC, 150 S. WACKER DRIVE, SUITE 2100, CHICAGO, IL, 60606, US

(21) Appl. No.: 12/105,611

(22) Filed: Apr. 18, 2008

Related U.S. Application Data
(63) Continuation of application No. PCT/US06/60077, filed on Oct. 19, 2006.
(60) Provisional application No. 60/727,847, filed on Oct. 19, 2005.
(60) Provisional application No. 60/729,230, filed on Oct. 24, 2005.

(51) Int. Cl. H01S 5/00; H01L 21/02

(52) U.S. Cl. 372/46.013; 438/38; 257/E21.002

(57) ABSTRACT

Disclosed is an example method to reduce waveguide scattering loss. The method includes forming a waveguide having a sidewall, the waveguide including a group III-V compound semiconductor material, and growing a native oxide on the waveguide to form an index of refraction contrast at the sidewall, the native oxide grown in a controlled Oxygen-enriched water vapor environment to reduce a roughness of the sidewall.

### RELATED APPLICATION

This application claims priority to U.S. Provisional Patent Application No. 60/727,847, entitled “Oxidation Smoothing of AlGaAs Heterostructures,” filed on Oct. 19, 2005, U.S. Provisional Patent Application No. 60/729,230, entitled “High-Index Contrast Ridge Waveguide Laser Structure,” filed on Oct. 24, 2005, and this application is a continuation of International Application No. PCT/US2006/060077 entitled “High-Index-Contrast Waveguide,” filed Oct. 19, 2006, each of which are hereby incorporated by reference in their entirety.

### GOVERNMENT INTEREST STATEMENT

This disclosure was made, in part, with United States government support under Grant No. ECS-0123501 awarded by the National Science Foundation. The United States government has certain rights in this invention.

### FIELD OF THE DISCLOSURE

This disclosure relates generally to group III-V semiconductor waveguides and lasers, and, more particularly, to high-index-contrast waveguide apparatus and methods for manufacturing the same.

### BACKGROUND

High-density photonic integrated circuits typically require a high index contrast (HIC) waveguide structure with an index contrast (Δn) that is greater than 1. The index contrast (Δn) is the difference between a core layer index of refraction and a cladding layer index of refraction. However, such a high index contrast has proven difficult to achieve concurrently with a smooth cladding layer/core layer interface.

In particular, scattering losses for a ridge-type waveguide are strongly impacted by roughness at the core/cladding interface. A Tien model predicts that the waveguide scattering loss increases in direct proportion to the product of the square of the root-mean-square (RMS) average surface roughness (σ)² of the waveguide with the square of the core-cladding index contrast (Δn)², i.e., Loss=(Δn)²(σ)².

Some efforts to minimize such scattering loss have focused on various dry etching techniques, but little success is known to have been realized. Oxidation smoothing techniques that employ wet oxidation have produced silicon-on-insulator (SOI) waveguides exhibiting significant reductions in propagation losses due to surface roughness. However, such success has not been observed with group III-V compound semiconductors, such as AlGaAs and/or GaAs, which are particularly dominant materials for optoelectronic devices (active and passive).

### BRIEF DESCRIPTION OF THE DRAWINGS

FIG. 1 is an example ridge semiconductor illustrating oxidation selectivity within an oxygen plus water vapor mixed environment and a non-oxygen enriched water vapor environment.

FIG. 2 is an example heterostructure waveguide with a rib geometry oxidized in an oxygen-enriched water vapor environment.

FIG. 3 is a conventional fabrication process and an example non-selective oxidation fabrication process for ridge waveguides.

FIG. 4 is an example plot of scattering loss versus sidewall roughness.

FIG. 5 is an example plot of scattering loss versus waveguide width.

FIG. 6 is a beam propagation method layout for an example simulation of sidewall roughness.

FIG. 7 is an example simulated waveguide cross section.

FIG. 8 illustrates example waveguide light propagation simulated for various sidewall roughness conditions.

FIG. 9 is an example process for oxidation smoothing of silicon on insulator (SOI) rib waveguides.

FIG. 10 illustrates example images of sidewall roughness before oxidation smoothing and after oxidation smoothing of SOI rib waveguides.

FIG. 11 is an example plot of output power versus waveguide length with and without oxidation smoothing.

FIG. 12 illustrates example atomic force microscopy images of AlGaAs surfaces before and after oxidation smoothing.

FIG. 13 illustrates example scanning electron microscope images of ridge structures after conventional wet thermal oxidation and non-selective oxidation.

FIG. 14 illustrates example scanning electron microscope top-view images of oxide/semiconductor interfaces after conventional wet thermal oxidation and non-selective oxidation.

FIG. 15 illustrates example scanning electron microscope images of wet thermal oxidation at various temperatures and added oxygen concentrations.

FIG. 16 illustrates example scanning electron microscope images of an etched AlGaAs ridge structure after non-selective oxidation.

FIG. 17 illustrates example scanning electron microscope images and beam propagation method simulations of heterostructure waveguides experiencing non-selective oxidation.

FIG. 18 is an example plot of simulated Fabry-Perot fringes of transmission versus phase at various loss levels.

FIG. 19 is an example schematic of a single quantum well (SQW) graded-index separate-confinement heterostructure (GRINSCH) laser and a conduction band diagram illustrating doping and Al composition profiles.

FIG. 20 illustrates example scanning electron microscope images of a GRINSCH ridge geometry laser wet oxidized laterally at various added oxygen concentrations, durations, and temperatures.

FIG. 21 is an example schematic of a GRINSCH laser diode having a straight Fabry-Perot resonance cavity, and a half-ring Fabry-Perot resonance cavity.

FIG. 22 is an example plot of a broad-area laser showing threshold current density versus inverse laser cavity length.

FIG. 23 is an example plot of output power versus injection current and voltage versus injection current for 5 μm wide native oxide-confined GRINSCH ridge waveguide lasers.

FIG. 24 is an example plot of total output power versus injection current for a narrow stripe laser.

FIG. 25 is an example plot of laser threshold current density versus inverse laser cavity length for broad-area and narrow stripe lasers.

FIG. 26 is an example plot of slope efficiency versus laser cavity length for broad-area and narrow stripe lasers.

FIG. 27 is an example SEM cross-section image of a multi-quantum-well RWG structure.

FIG. 28 is an example plot of total power versus injection current for conventional and HIC RWG lasers.

FIG. 29 is an example plot of threshold current density versus laser stripe width for conventional and HIC RWG lasers.

FIG. 30 is a schematic of an example experimental setup for measuring laser diode spectral characteristics.

FIG. 31 is an example plot of spectrum characteristics of a high-index contrast straight ridge waveguide laser diode.

FIG. 32 is an example plot of wavelength versus injection current for various width lasers at room temperature.

FIG. 33 is an example plot of wavelength versus injection current density for various width lasers at room temperature.

FIG. 34 is an example plot of intensity versus wavelength for a high-index contrast straight ridge waveguide laser diode.

FIG. 35 is an example schematic of a conventional edge-emitting laser diode showing elliptical far-field radiation and beam astigmatism pitfalls.

FIG. 36 illustrates example beam propagation method images of passive waveguide structures having various ridge waveguide structures.

FIGS. 37 and 38 are an example plots of far-field radiation patterns parallel and perpendicular to a junction plane for laser diodes of various stripe widths.

FIG. 39 is an example schematic of astigmatism in index-guided and gain-guided lasers.

FIG. 40 is an example plot of total power versus injection current for a GRINSCH HIC RWG stripe geometry laser with uncoated facets.

FIGS. 41A and 41B are example plots of near-field and far-field profiles.

FIG. 43 is an example plot of power fraction versus polarization angle for a native oxide-confined ridge waveguide laser.

FIG. 44 is an example plot of polarization power ratio versus stripe width at varying power levels.

FIG. 45 is an example plot of free spectral range versus index contrast, and bending radius versus index contrast.

FIG. 46 is an example plot of total output power versus injection current for pulsed native oxide-confined half-ring resonator lasers.

FIG. 47 is an example plot of total output power versus injection current, and voltage versus injection current for PECVD SiO₂-confined half-ring lasers.

FIG. 48 is an example plot of threshold current density versus inverse laser cavity length for straight broad area and narrow stripe lasers.

FIG. 49 illustrates example plots of total output power versus injection current for native oxide-confined half-ring lasers having various radii, threshold current density versus bending radius, and slope efficiency versus bending radius for such lasers.

FIG. 50 illustrates optical microscope images for half-ring laser patterns.

FIG. 51 is an example plot of relative intensity versus injection current of a native oxide-confined half-ring laser.

FIG. 52 is an SEM cross-sectional image of an HIC RWG structure after etching and oxidation.

FIG. 53 is an example plot of total power versus injection current for half-racetrack-ring lasers with various radii.

FIG. 54 is an example plot of FWHM for half-racetrack-ring resonators.

FIG. 55 is an example plot of threshold current density versus inverse cavity length.

FIG. 56 is an example plot of total power versus injection current for PECVD SiO₂-confined lasers and pulsed, quasi-continuous-wave, and true continuous-wave native oxide-confined lasers.

FIG. 57 is an example plot of threshold current density versus laser stripe width and threshold current versus laser stripe width for native oxide-confined lasers and PECVD SiO₂-confined lasers.

FIG. 58 illustrates example plots of inverse differential quantum efficiency versus cavity length, internal quantum efficiency versus laser stripe width, and internal loss versus laser stripe width for lasers of varying stripe widths.

### DETAILED DESCRIPTION

High index contrast (HIC) optical waveguides permit a move towards very large scale integration of photonic integrated circuits (PICs), mainly because of the very small bending radius achievable with HICs. A self-aligned fabrication process combining a dry etching technique and a non-selective oxidation technique for AlGaAs heterostructures enables formation of a layer of native oxide on the sidewall of a waveguide. Additionally, native oxide is formed on the base of an etch-defined mesa, both of which simplify the fabrication process by simultaneously providing electrical insulation (eliminating need for a deposited dielectric and additional mask step) and effective optical mode confinement. A technique herein referred to as “oxidation smoothing” allows ultra-low loss submicron waveguides for group III-V compound semiconductor heterostructures via non-selective wet thermal oxidation. Improved device performance including, but not limited to, low threshold current and high efficiency may be achieved for HIC laser diodes both in straight and curved geometries, indicating a low surface state density at the semiconductor/oxide smoothed interface. Such techniques further enable a small (e.g., r=10 micron) radius half-ring laser diode to be realized. The potential of the HIC laser structure to overcome longtime limitations in edge-emitting lasers of asymmetric beam divergence and large astigmatism are also enabled with the oxidation techniques described below.

The boom and bust of information networks in the macroscopic world has been a driving force behind the accelerated shrinkage of electronic devices in the microscopic world, especially since the introduction of integrated circuits (ICs). Additionally, because photonic integrated circuits (PICs) are a major component in telecommunications systems, efforts to shrink devices used in optical networks are ongoing.

One parameter in guided wave theory is the core-cladding index contrast (Δn), which presents a promising research avenue for new optical system breakthroughs. HIC devices with Δn>1 may simultaneously allow the growth of device density and greater integration complexity with the same basic set of materials and processes. A smaller PIC footprint and the potential for large free spectral range (FSR) resonators give researchers reasons to believe that HIC photonic devices will soon play a leading role in numerous applications.

The success of HIC passive waveguide devices made on silicon-on-insulator (SOI) substrates has naturally extended people's interest to the group III-V semiconductors, which are currently the dominant materials for most active optoelectronic devices. Due to the low refraction index (n) of dielectrics (e.g., n˜1.5-2), both native oxides and chemical vapor deposition (CVD) dielectrics can offer a large index contrast semiconductor/dielectric interface.

Enhanced oxidation rates of low Al-ratio AlₓGa₁₋ₓAs and reduced oxidation rate selectivity of Al content are accomplished, in part, by the controlled addition of trace amounts of O₂ (0-10000 ppm (1%) relative to N₂) to the process gas stream (N₂+H₂O vapor). Accordingly, low Al-ratio AlGaAs waveguide core regions can be oxidized laterally through this non-selective wet thermal oxidation technique without fully oxidizing the higher Al-ratio cladding layer(s), thereby allowing a much higher, real lateral index step (Δn˜1.7) to be achieved.

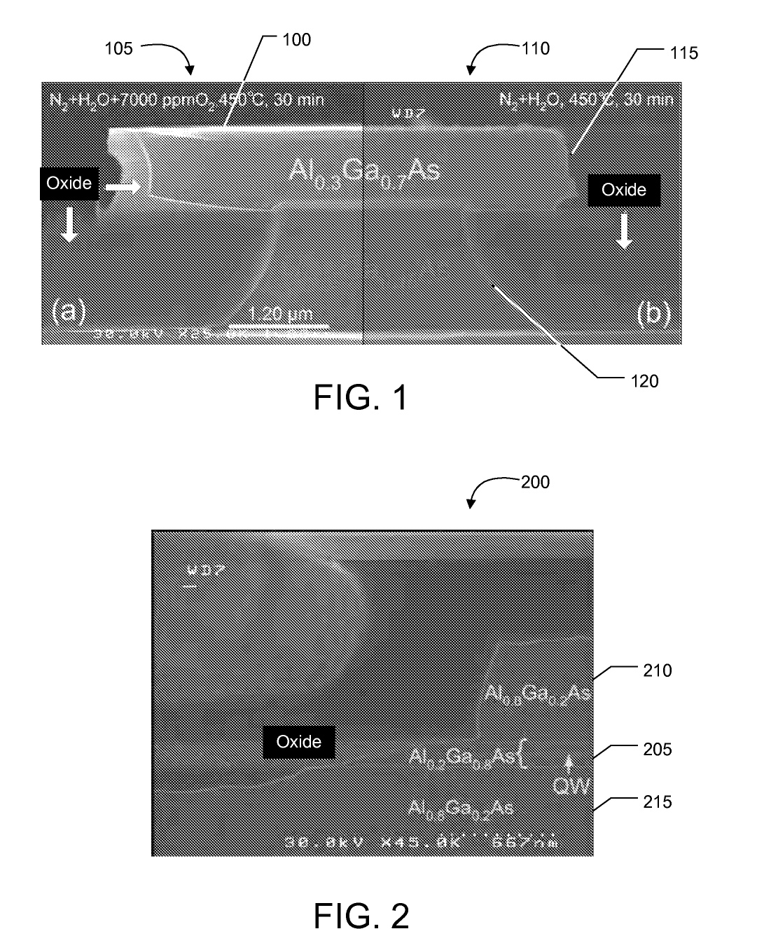

FIG. 1 shows an example ridge geometry 100 in which the oxidation rates of Al_{0.3}Ga_{0.7}As and Al_{0.85}Ga_{0.15}As have been enhanced to differing degrees as a result of an addition of 7000 ppm O₂ participation in a conventional oxidation environment. FIG. 1 illustrates the ridge geometry 100 oxidized laterally in side (a) 105 and side (b) 110. Side (a) 105 is exposed to ultra high purity (UHP) N₂, and H₂O at 450° C. for 30 minutes in an environment mixed with 7000 ppm O₂, while side (b) 110 does not include such O₂ addition. A top epi-layer 115 is made of Al_{0.3}Ga_{0.7}As and a bottom epi-layer 120 is made of Al_{0.8}₅Ga_{0.15}As. On side (b) 110, only the bottom layer 120 is oxidized to a depth of approximately 2.3 micro-meters (μm), while the top layer remains unoxidized. However, on side (a) 105 the oxidation rate selectivity with Al content is reduced and the top layer 115 is oxidized along with the bottom layer 120, with a lateral oxidation depth of approximately 0.41 μm. The oxidation selectivity significantly decreases due to a much higher enhancement in the oxidation rate of low Al-ratio AlGaAs than that of high Al-ratio AlGaAs.

At least one approach to realize an HIC semiconductor/oxide interface at the waveguide core has been simply to perform a deep oxidation from the unetched upper cladding surface. However, the isotropic property of the thermal oxidation (even for non-selective oxidation) results in significant laser oxide growth in the high-Al-content upper cladding layer before the oxidation front penetrates the core region, resulting in poor waveguide dimension control. FIG. 2 illustrates a heterostructure waveguide 200 having a quantum well (QW) 205 made of Al_{0.2}Ga_{0.8}As that resides between an upper layer 210 and a lower layer 215, each made of Al_{0.8}Ga_{0.2}As. The waveguide 200 is oxidized laterally in 7000 ppm O₂+N₂+H₂O at 450° C. for 30 minutes. As shown in FIG. 2, the situation is not significantly improved by partially removing the upper cladding followed by the non-selective oxidation due to the still high oxidation rate selectivity of the high Al-ratio upper cladding to the low Al-ratio waveguide core.

In order to fully maintain the critical dimension, dry etching through the core layer, leading to a ridge waveguide (RWG) geometry with an even higher index contrast (Δn˜2.29) at the semiconductor/air interface, appears to be reasonable and straightforward. However, this approach is usually avoided for active devices (e.g., diode lasers) in order to prevent surface states created at an exposed, etched surface. Such surface states may lead to nonradiative interface recombination, robbing carriers from the active region and reducing the device efficiency. At the same time, the tight mode confinement due to a high index contrast (Δn) causes the waveguide single mode dimension to shift towards much smaller (often submicron) values, creating new potential challenges for lithography and etching. Furthermore, HIC waveguide devices are typically characterized by poor tolerance to bend and scattering losses, which increase much more rapidly for a high index contrast (Δn) in proportion to the side wall roughness (SWR). Other critical concerns including, but not limited to, surface states and carrier confinement have to be taken into account for active devices, as well. On the other hand, potential for HIC devices to provide more advanced and complex integration and enhanced device performance motivate considerable research in this area. Additionally, reducing processing requirements may lead to significant cost reductions of III-V semiconductor PICs, thereby providing further research motivation.

### Fabrication

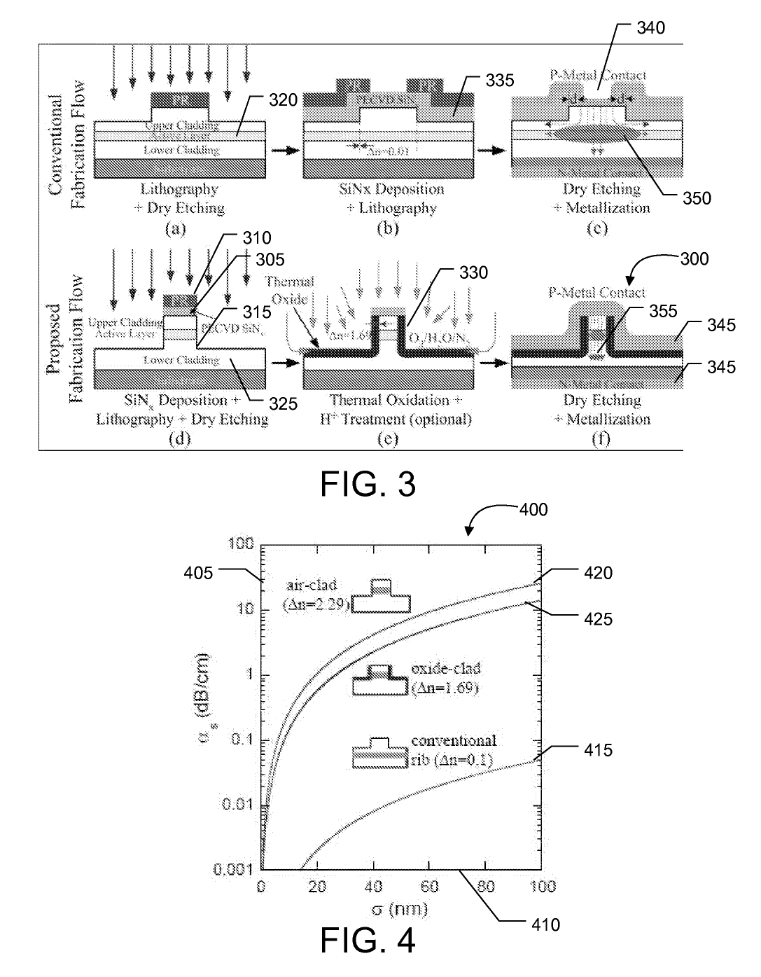

Based on the concerns above, a simple, self-aligned deeply-etched and wet thermally oxidized GaAs-based RWG laser fabrication process is realized. The aforementioned process allows fabrication of high-performance and low-cost passive and active HIC devices using commonly available microelectronics manufacturing facilities. FIG. 3 illustrates a conventional process flow (a, b, and c) compared to an example process flow (d, e, and f) for oxide-defined HIC RWG lasers 300. Without limitation, the example fabrication of passive waveguides is substantially identical to the laser fabrication shown in FIG. 3, except that the current confinement and metallization issues need not be taken into account.

In the illustrated example, fabrication starts with a ˜200 nm CVD SiNₓ deposition 305 to protect the p+-GaAs cap layer from later oxidation. A waveguide stripe is then patterned through conventional photolithography followed by two successive dry etching steps to transfer the photoresist (PR) 310 pattern to the SiNₓ layer and semiconductor epilayers, forming a ridge 315 as shown in (d) of FIG. 3. Unlike the conventional dry etching stopped above the active layer in the upper cladding layer 320 (shown in (a) of FIG. 3) to prevent introduction of defects by etching only far away from the active region, dry etching in this case reaches the lower cladding layer in order to keep the waveguide lateral dimension equal to that of the PR mask. The nonradiative recombination defects formed during this initial etching process are substantially reduced during the following non-selective oxidation. As shown in (e) of FIG. 3, the oxide 330 grown on the waveguide sidewalls results in a HIC (Δn˜1.7) semiconductor/oxide interface, enabling the realization of a HIC RWG capable of supporting very sharp bending (e.g., 10 μm), while simultaneously providing scaling from a conventional-lithography-defined ridge dimension (≧1 μm) to the submicron dimensions required for HIC waveguide single-mode operation. Furthermore, instead of depositing PECVD SiO₂ or SiNₓ for electrical confinement and surface passivation (shown in (b) of FIG. 3) the native oxide itself acts directly as the dielectric layer, providing a self-aligned process which eliminates the potential alignment errors and the narrowing of the top contact area (shown as 335 by two “d”s (340) in (c) of FIG. 3), unavoidably resulting from a second “current-window open” lithography step in a conventional fabrication process flow. In the disclosed example process, a final dry etching procedure then selectively removes the dielectric stripe mask 305, using special care to prevent etch damage to the p+-GaAs cap layer, and the wafer is then thinned, metallized 345 and cleaved into bars for laser characterization.

The shallow etch in the conventional process flow shown in (a) of FIG. 3 yields a small effective index step (Δn˜0.01), shown laterally in (b) of FIG. 3, which provides relatively weak optical mode confinement in the horizontal direction and leads to at least two undesirable effects: current spreading and output beam asymmetry 350, as shown in (c) of FIG. 3. The significant current spreading (tens of microns) that plagues conventional RWG laser designs is prevented in this example case because, in part, current flow is effectively restrained to a vertical channel 355 defined by the insulating oxide. As shown in (f) of FIG. 3, strong optical mode confinement from the vertical oxide walls also offers a potential for overcoming the limitation of the asymmetric optical mode profile and output beam in-plane versus out-of-plane far-field divergence in edge-emitting lasers, which is a well known disadvantage that hinders efforts to couple output power to optical fibers and becomes problematic in other applications, such as for optical disk read/write beams and/or laser printing.

As discussed in further detail below, non-selective native oxidation is also discovered in this work as a key step to significantly reduce semiconductor waveguide scattering loss through an effect known as “oxidation smoothing,” in which a thermal oxidation process smoothes the etched SWR as the oxidation front progresses inward. Compared with the lithography and etching for submicron features, the non-selective oxidation is controllable for formation of submicron structures by the tuning of several process parameters including, but not limited to temperature, O₂ concentration, and/or flow rate of an N₂ carrier gas, all of which may be realized with lower cost equipment. The example HIC process clearly can provide a significant improvement in the device performance/cost ratio.

Relying on the high-quality thermal oxide of lower Al content AlGaAs layers (formed through O₂ enhanced wet thermal oxidation), a high quantum efficiency ridge waveguide graded-index separate-confinement heterostructure (GRINSCH) straight laser and sharply-curved resonator GRINSCH laser is realized having a small bend radius, such as for example 10 μm to 50 μm.

### Sidewall Roughness and Scattering Loss

Factors that contribute to the waveguide loss include, but are not limited to absorption, owing to free carriers and defects in the bulk waveguide materials, scattering from defects and from the core/cladding interfaces, and coupling of the evanescent field of the propagating modes into the substrate. For the cases of passive AlGaAs/GaAs waveguides, absorption from free carriers and defects and scattering from core/cladding interfaces can be negligible using today's well-proven high-quality doping-free epitaxy growth technique. The loss due to GaAs substrate coupling is typically negligible when a relatively thick AlGaAs lower cladding layer is employed. Hence, the scattering from sidewall roughness introduced during processing rather than from dislocations or other defects generated in the material growth remains a critical factor for low-loss light propagation. Persons of ordinary skill in the art appreciate that the sidewall roughness is responsible for the scattering loss from waveguide sidewalls. Scattering due to sidewall roughness poses a major challenge for high-Δn systems based on, in part, a Tien model (shown as Equation 1) based on the Rayleigh criterion.

$${α}_{s} = \frac{{α}^{2} {k}_{0} {{hE}_{s}^{2} ( Δ n )}^{2}}{β \int {E}^{2} d x} \qquad Equation 1$$

The model predicts that the increase in waveguide scattering loss αₛ is directly proportional to the product σ²(Δn)² where σ is the root-mean-square (RMS) surface roughness of a waveguide with core cladding effective index contrast (Δn).

More rigorous autocorrelation models accounting for spatial periodicities and the scattering roughness coherence length even predict that αₛ increases in proportional to (Δn)³. With the device size shrinkage down to only an order of magnitude larger than that of the sidewall roughness, propagation loss due to the rough sidewalls may be significant. FIG. 4 illustrates a dependence graph 400 of scattering loss 405 versus sidewall roughness 410 for different Δn structures. Based on the aforementioned Tien model, FIG. 4 illustrates scattering loss on RMS average sidewall roughness σ, for 3 ridge waveguide structures of different lateral index contrast: a conventional shallow-etched ridge with Δn=0.1 (415), a deeply-etched, air-clad ridge with Δn=2.29 (420), and our example oxide-confined ridge with Δn=1.69 (425).

While an air-clad structure is not widely employed for active injection lasers for reasons discussed above, it has been used for passive AlGaAs/GaAs microring resonator devices which were fabricated using extensively optimized inductively coupled plasma (ICP) reactive ion etching (RIE) or chemical-assisted ion beam etching (CAIBE) to achieve SWR in the 10-20 nm range. While 1-2 nm sidewall roughness can be achieved for InP-based with optimized ICP-RIE, the state-of-the-art in AlGaAs has not previously realized low roughness in this manner due to, in part, effects of high chemical reactivity of Al on the etching mechanism. Sidewall roughness achieved in a Plasma-Therm 790 RIE tool used in this work is frequently in the 50-100 nm range, corresponding to αₛ range of 3-30 dB/cm for HIC RWGs (air-clad & oxide-clad), which is not acceptable for fiber-optic telecommunications.

A different model leading to Equation 2, shown below, demonstrates how waveguide scattering loss rises dramatically when the waveguide width is pushed towards submicron dimensions for single-mode operation.

$${α}_{s} = \frac{{σ}^{2}}{\sqrt{2} {k}_{0} {d}^{4} {n}_{1}} {gf}_{e} \qquad Equation 2$$

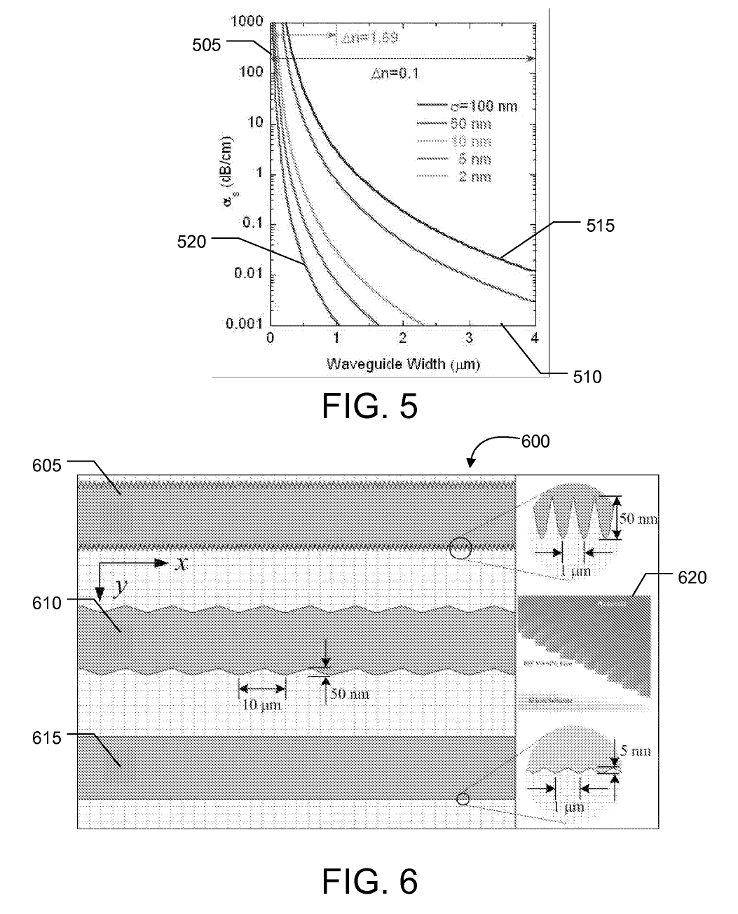

In Equation 2, k₀, d and n₁ are the free-space wave number, the waveguide half width and the effective core index, respectively. Additionally, g and fₑ are functions of the effective core/cladding indices and wavelength. FIG. 5 illustrates scattering loss versus waveguide width for different sidewall roughness values. Single-mode operation ranges are specified for waveguides with index contrast values of Δn=0.1 and 1.69. Using Equation 2, FIG. 5 plots the scattering loss 505 versus waveguide width 510 for several values of sidewall roughness from σ=2 nm through 100 nm. Based on beam propagation method (BPM) simulations, single mode regions for waveguides with index contrast of Δn=0.1 and 1.69 have a waveguide width of approximately 4 μm and 1 μm, respectively. As such, single-mode HIC waveguides are much more vulnerable to scattering loss induced by SWR than multi-mode waveguides. For example, at a waveguide width of 1 (the cut-off point for higher order modes when Δn=1.69 for an oxide cladding waveguide), FIG. 5 illustrates that the loss with σ=100 nm (515) is larger by a factor of >1000 than that of a waveguide having σ=2 nm (520).

BPM simulations using Opti-BPM® software (version 7.0.1) from Optiwave®, Corp. (Ottawa, Canada) have also been performed to demonstrate the loss effect of scattering loss during light propagation. To simulate the effect of sidewall roughness, the roughness is simplified to a Sinusoidal sidewall deviation, which is reasonable because any arbitrary deviation from straightness can result from the superposition of a series of Sinusoidal waves. Any PR stripes with a wave-like edge are generally believed to result from interference effects during the contact photolithography. FIG. 6 illustrates BPM layout top views 600 for simulation of sidewall roughness of AlGaAs RWGs (w=1 μm) having three different degrees of SWR. In the illustrated example, the first (top) RWG 605 has a roughness (σ) of 50 nm with a roughness period (Λ) of 1 μm, the second (middle) RWG 610 has a roughness of 50 nm with a roughness period of 10 μm, and the third (bottom) RWG 615 has a roughness of 5 nm with a roughness period of 1 μm. An SEM image 620 of a photoresist etch mask having a wave-like sidewall roughness matching the simulation parameters in the second RWG 610 is shown.

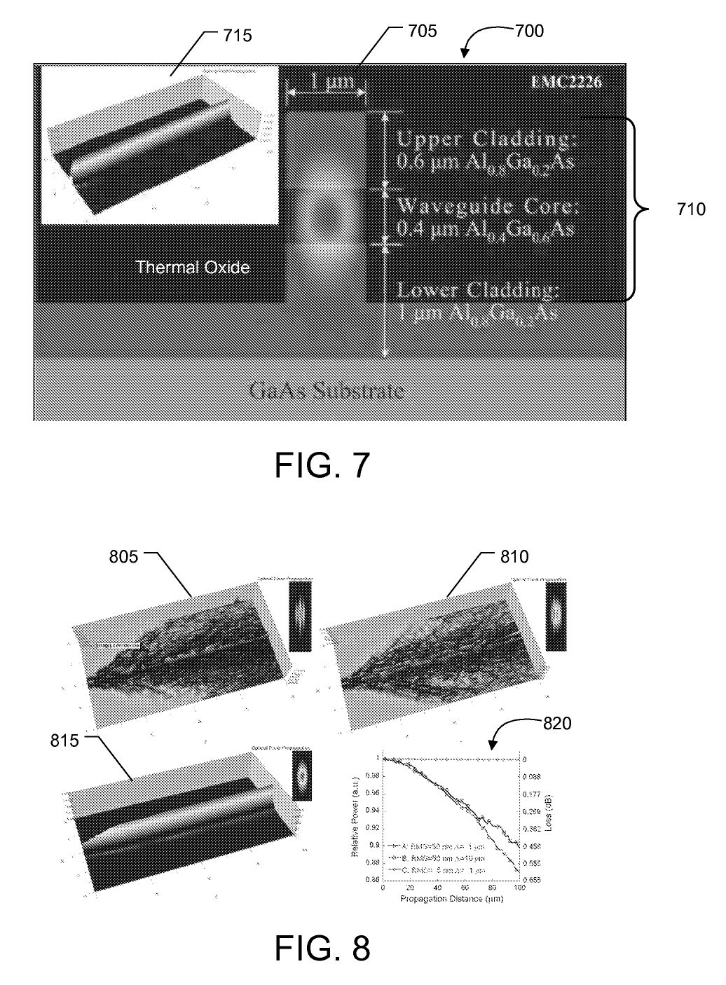

For the BPM simulations here, the vertical waveguide structure (into the page for 605, 610, and 615) includes a 0.4 μm Al_{0.8}Ga_{0.2}As waveguide core layer sandwiched by a 0.6 μm Al_{0.4}Ga_{0.6}As upper cladding layer and a 1 μm Al_{0.8}Ga_{0.2}As lower cladding layer. The effective index method is used to reduce the 3-dimensional structure to a 2-dimensional waveguide for 2-D BPM simulations. FIG. 7 illustrates a first-order mode for the AlGaAs ridge waveguide 700 with a 1 μm width (705) and a 1.5 μm waveguide ridge height (710). An inset 715 illustrates that light propagates in an X-Z plane. The ridge waveguide 700 is covered by a wet thermal native oxide, resulting in a lateral HIC of Δn=1.69 in the core layer. This consequently makes the beam propagation simulated via 2D BPM very sensitive to sidewall roughness at the waveguide core and oxide interface.

For the case of a sinusoidal (sine) wave roughness profile, the roughness parameter (σ) is related to the amplitude of the sine wave with wave period (Λ). The three RWG waveguides with variable sidewall profiles shown in FIG. 6 are chosen for BPM simulations. As discussed below, the simulations demonstrate how both σ and the roughness period Λ affect the light propagation through scattering from the sidewall. The BPM simulation results for the three cases of FIG. 6 having varied σ and Λ are shown in FIG. 8. Each of the illustrated examples of FIG. 8 employs light propagation for 100 μm in X-Z planes. The first example 805 corresponds to 605 of FIG. 6 (roughness (σ) of 50 nm with a roughness period (Λ) of 1 μm), and the second example 810 corresponds to 610 of FIG. 6 (roughness of 50 nm with a roughness period of 10 μm), and the third example 815 corresponds to 615 of FIG. 6 (roughness of 5 nm with a roughness period of 1 μm). In the illustrated example, a plot 820 shows light propagations for the three examples (805, 810 and 815) and relative power loss at the end of waveguides.

FIG. 8 illustrates that both a decrease in the roughness amplitude a and an increase in the period Λ, achievable through photolithography optimization and oxidation smoothing (discussed below) reduce the loss to varying degrees. When σ decreases 10 times from 50 nm in the first example 805 to 5 nm for the third example 815, the waveguide scattering loss drops dramatically from about 13% power loss to less than 0.07% after light propagation for 100 μm, giving an approximately 180-fold loss reduction, comparable to the theoretical simulations shown in FIGS. 4 and 5. Additionally, by comparing the first example 805 and the second example 810, the impact of Λ on the scattering loss is not as pronounced as that of σ. For the constant σ=50 nm, a period increase from Λ=1 μm (the first example 805) to Λ=10 μm (the second example 810) results in only a 3% power recovery (i.e., an increase in the propagated power at 100 μm from 87% to 90%). The actual 3D roughness profile has been simplified to periodical sine wave cases in the x-y 2D plane here for ease of simulation in the BPM software. This is reasonable given that the scattering resulting from the roughness along the light propagation direction (y-axis) dominates the total scattering loss. The simulations demonstrate, in part, the huge impact of sidewall roughness on the wave propagation loss in compact HIC RWG devices.

Various approaches have been applied to reduce waveguide sidewall roughness, including: optimization of the photolithography process; etching the ridge in wet solutions; and using reactive ion beam etching (RIBE) and ICP-RIE to achieve better etching profile control. However, an isotropic property inherent in many wet etching processes results in an undercutting beneath the mask, which is undesirable for PICs due to the loss of dimension control. RIBE and ICP-RIE have been utilized widely in industry because of their optimized anisotropic etching and reduced sidewall damage, but the cost of these systems prevent them from completely replacing conventional RIE, particularly for university-level research. For silicon-on-insulator (SOI) structures, a partial oxidation is typically an effective technique for smoothing an etched interface due to the isotropic nature of the thermal oxidation process as the oxidation front progresses inward.

Initial studies of the oxidation smoothing process have been performed on SOI substrates where the oxidation process is relatively easy to control because of the simple elemental semiconductor crystalline structure compared to compound semiconductors. Moreover, SiO₂ can be removed by buffered HF (BHF) acid with extremely good selectivity to Si, thereby enabling access to inspect the resulting interface via scanning electron microscope (SEM) to optimize the oxidation parameters.

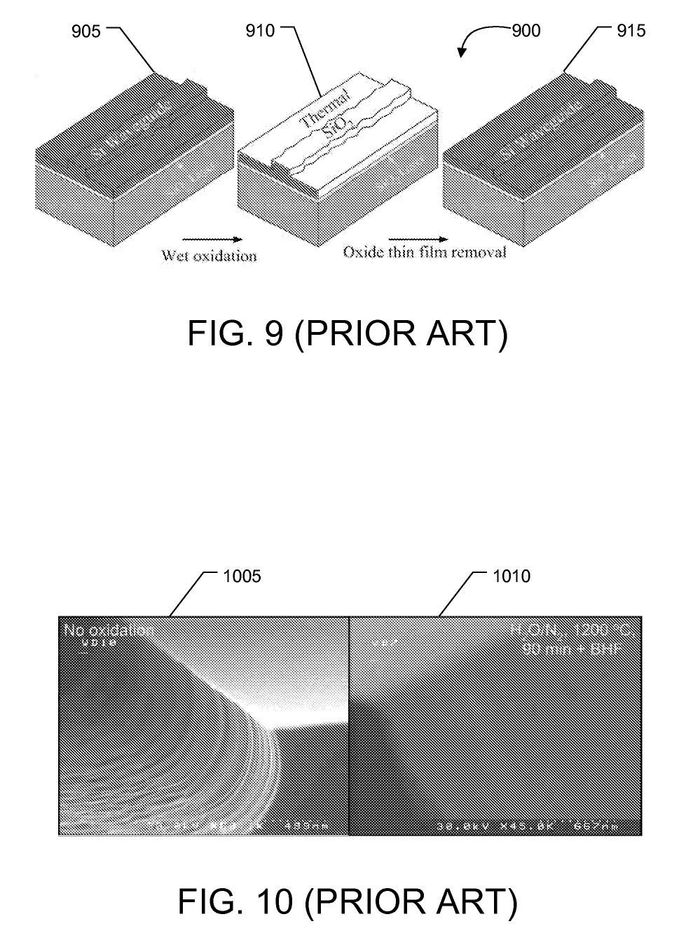

The entire process 900 for oxidation smoothing is schematically presented in FIG. 9. SOI rib waveguide fabrication starts from conventional contact lithography 905 and RIE (SF₆/O₂) etching, followed by wet thermal oxidation 910 and thermal SiO₂ removal with BHF solution 915.

FIG. 10 illustrates sidewall roughness of an SF₆ etched SOI waveguide before oxidation smoothing 1005, and after oxidation smoothing plus oxide removal by BHF 1010. From the left SEM image 1005 in FIG. 10 showing a ridge after RIE etching, the initial sidewall roughness is estimated as ˜80 nm. However, the right SEM image 1010 in FIG. 10 illustrates that after Si oxidation for 90 minutes @1200° C. followed by BHF oxide removal, the sidewall roughness is reduced to less than ˜10 nm. For the oxidation with the same duration at 1100° C., the roughness is reduced down to just 50 nm (not shown). Therefore, it appears that at higher oxidation temperatures, a smoothed interface is obtained faster due to higher rates. Special polishing equipment commonly used for polishing transmission electron microscopy (TEM) samples may be subsequently employed to polish end facets perfectly vertical to the waveguide stripes to prepare the waveguides for optical coupling and loss measurement.

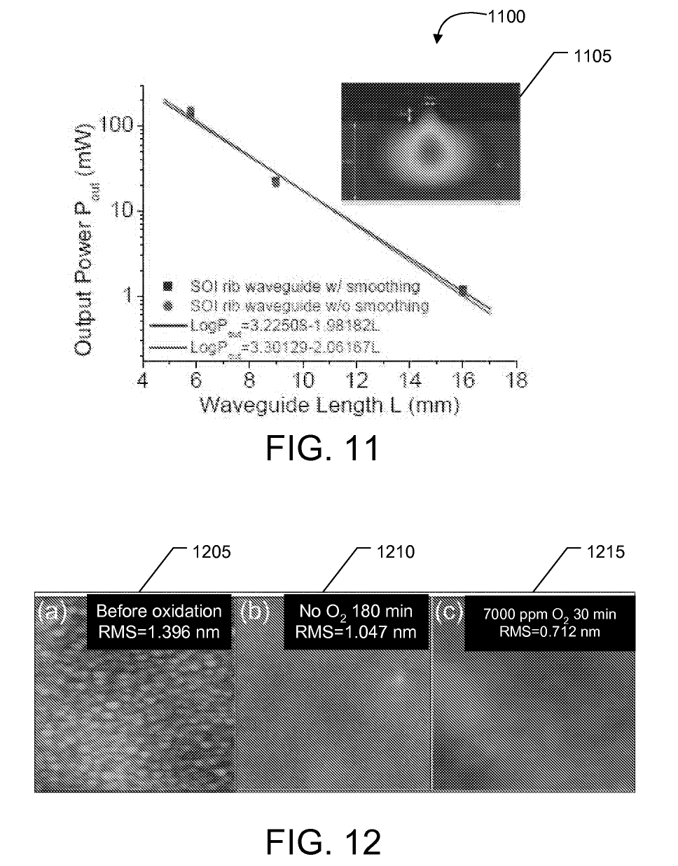

Waveguide propagation loss has been characterized for 1.55 μm input light through conventional cut-back measurement. FIG. 11 illustrates a plot 1100 of the cut-back loss measurement for SOI rib waveguides with and without oxidation smoothing. An inset 1105 illustrates an optical mode cross-section by OPTI-BPM simulation. FIG. 11 shows the measured data and linear fit for the SOI rib waveguides with an 8 μm rib width and a 1.5 μm rib height. Optimized oxidation smoothing is applied to the waveguides after the first round of loss measurements. However, no distinguishable improvement is achieved, presumably because light guided in the SOI rib waveguide for this case is mostly confined under the rib as the simulation in the inset 1105 of FIG. 11 shows, indicating minimal influence through interactions with the sidewall interface. Unlike the cases for RWG simulated earlier, the smoothing effect is therefore largely weakened. This is consistent with FIG. 5, which shows that sidewall roughness impacts narrower (e.g., w<4 μm) waveguides much more significantly. The ˜2 dB/cm waveguide propagation loss also indicates the other possible waveguide imperfections other than sidewall roughness or issues with measurement errors. FIG. 11 is used here to illustrate one of the common methods for characterizing waveguide propagation loss. A more precise measurement method known as the “Walker” method based on Fabry-Perot resonance is discussed below to characterize AlGaAs/GaAs RWGs with improved accuracy especially for loss coefficients less than 1 dB/cm.

### Oxidation Smoothing Study for the Compound Semiconductor AlGaAs

Success achieved on SOI substrates clearly indicates the viability and significance of oxidation smoothing. However, to extend this process for substantial roughness reduction to III-V compound semiconductors is not at all trivial because oxidation kinetics for an alloy of group III and V elements are much more complicated than that of elemental silicon and result in a diversity of oxides (Ga₂O₃, As₂O₃, Al₂O₃, etc.). The surface roughness reduction on the native oxide surface after the wet oxidation is first demonstrated on a RIE-etched Al_{0.3}Ga_{0.7}As sample. FIG. 12 illustrates atomic force microscopy (AFM) images to highlight RMS values of surface roughness of Al_{0.3}Ga_{0.7}As samples. A first sample 1205 is intentionally roughened by RIE, and a second sample 1210 is oxidized in UHP N₂+H₂O for 180 minutes at 450° C., and a third sample 1215 is oxidized in UHP N₂+7000 ppm O₂+H₂O for 30 minutes at 450° C. The first sample 1205 shows the AFM image of the intentionally roughened Al_{0.3}Ga_{0.7}As surface before oxidation so that the degree of roughness reduction following both conventional wet oxidation for 180 min at 450° C., and non-selective oxidation with the addition of 7000 ppm O₂ for 30 min at 450° C. can be compared. A denser oxide and its more rapid formation process in the non-selective oxidation are two factors believed to together yield a greater surface roughness reduction than with conventional wet oxidation.

Smoothing of the oxide surface may be helpful for oxide waveguide applications. However, the smoothing of the oxide/semiconductor interface in this example is of greater concern for HIC waveguide devices than that of the oxide/air interface because propagating light interacts primarily with the former and is unlikely to penetrate the tight confinement of the low-index oxide lateral cladding to reach the latter.

A nonselective oxidation process accomplishes oxidation smoothing in AlGaAs, with wet oxidation proving ineffective without the addition of dilute O₂ to the process gas. FIG. 13 illustrates SEM images showing oxidation of AlₓGa₁₋ₓAs at 450° C. In particular, x is adjusted to realize varying oxidation rates. In the illustrated example, a first sample 1305 and a second sample 1310 each have a value of 0.3 for x (i.e., Al_{0.3}Ga_{0.7}As). The first sample 1305 is wet oxidized for 20 minutes with 7000 ppm O₂, while the second sample 1310 is wet oxidized in a conventional manner for 20 minutes without O₂. A third sample 1315 and a fourth sample 1320 each have a value of 0.5 for x (i.e., Al_{0.5}Ga_{0.5}As). The third sample 1315 is oxidized for 30 minutes with 7000 ppm O₂, while the fourth sample 1320 is oxidized for five hours without O₂. In the illustrated example FIG. 13, results of non-selective (left) vs. conventional (right) wet thermal oxidation on simple ridge structures defined in thick AlₓGa₁₋ₓAs epilayers by shallow dry etching (8 minutes in BCl₃/Cl₂/Ar by RIE) is thus shown for both x=0.3 (top) and x=0.5 (bottom) alloy compositions. These SEM images clearly show that for nonselective oxidation, initial rough sidewall features of ≧100 nm dimension are smoothed away at the inward progressing oxidation front, resulting in an apparent final sidewall roughness (at least in the cross section plane) as low as 1-2 nm RMS (as seen by the high magnification inset 1325). On the other hand, with no added O₂ (i.e., conventional wet oxidation), rough sidewall features do not disappear, and an even rougher interface results, shown by the high magnification inset 1330. For a longer (5 hr) conventional oxidization 1320 of Al_{0.5}Ga_{0.5}As to achieve a thickness comparable to the nonselective oxidation, no smoothing is achieved, indicating that the oxidation smoothing is mainly associated with the oxidation method. The smoothing extent is thus independent of the oxide thickness under conventional (no O₂) wet thermal oxidation.

The cracking of the oxide away from the semiconductor is observed after staining only in conventionally oxidized samples. As samples were prepared with identical etch staining procedures (HCl+H₂O₂+H₂O), the “crack” between AlGaAs and oxide in the second 1310 and fourth 1320 samples, but not in the first 1305 and third 1315 samples shows that the conventional oxide is less dense and robust, consistent with a previously observed lower refractive index. Such a large density of defects at the interface of crystalline AlGaAs and amorphous conventional oxide likely causes fast acid diffusion during etch staining, leading to the appearance of a crack.

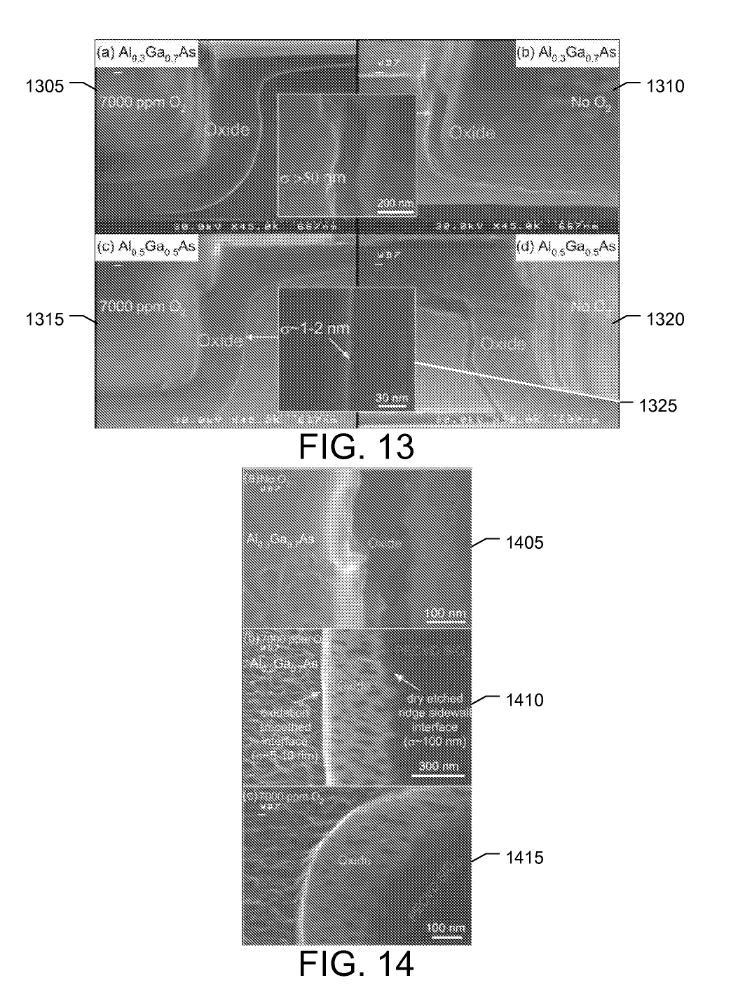

While the images in FIG. 13 demonstrate smoothing in a cross sectional view, the smoothness of the interface along the waveguide axis (into the page on FIG. 13) is more critical to determining the scattering loss, as was discussed above. FIG. 14 illustrates top view SEM images of oxide/semiconductor (Al_{0.3}Ga_{0.7}As) interfaces. A first image 1405 illustrates an interface without O₂ added during wet oxidation, while a second image 1410 illustrates an interface with 7000 ppm O₂ added, which results in a roughness reduction of 10 to 20 times. A third image 1415 illustrates that such beneficial smoothing is also realized on curved surfaces. In the illustrated example of FIG. 14, the specimens shown (first, second, and third images) were prepared by encapsulating the etched and oxidized ridge with 1 μm of PECVD SiO₂ to protect the rough outer interface, followed by standard lapping and polishing and subsequent light staining in HCl+H₂O₂+H₂O solution. The first 1405 and second 1410 images of FIG. 14 show the same result with and without O₂ participation as in FIG. 13, in which a significant roughness reduction occurs only with the addition of O₂ to the process gases. The “cracking” away of the conventional oxide from the semiconductor, shown in FIG. 13, is not observed in this lapped & polished sample due to the encapsulation by the PECVD SiO₂. The “speckles” on the oxide illustrated on the second 1410 and third 1415 images of FIG. 14 are remnants of the polishing slurries which are also responsible for the non-uniform AlGaAs surface after etch staining. Accordingly, FIGS. 13 and 14 illustrate that the isotropic smoothing of AlGaAs ridge structures via the non-selective oxidation process is effective in both dimensions.

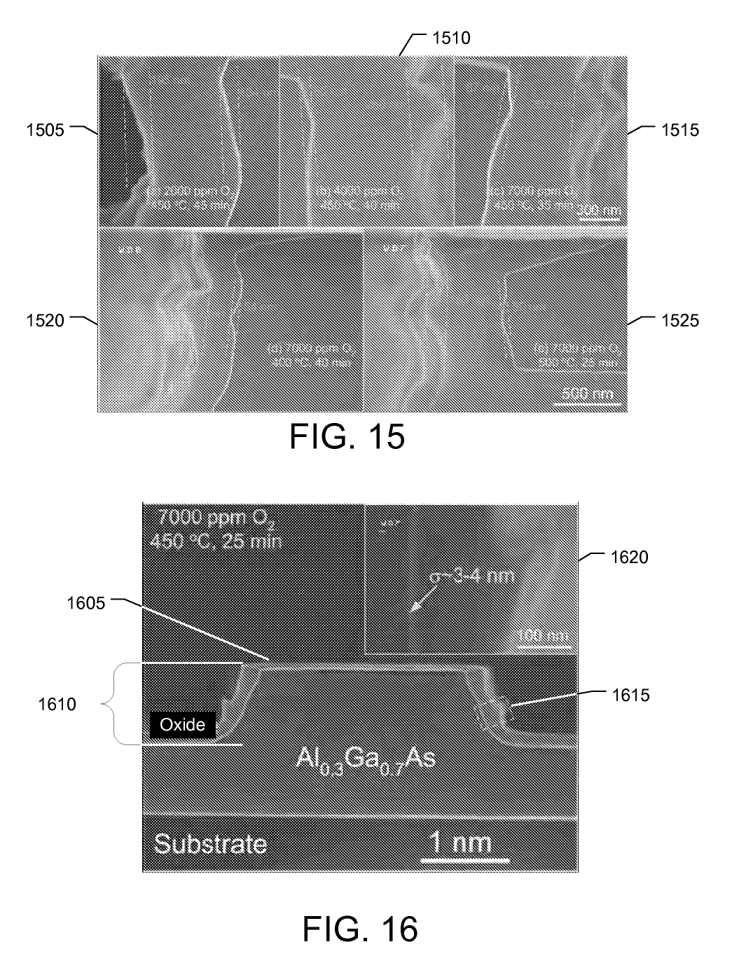

Two parameters playing important roles in the non-selective oxidation are process gas composition (O₂ content) and oxidation temperature. As the conventional wet oxidation without adding O₂ (e.g., 0 ppm O₂) is generally ineffective for roughness reduction, it is noteworthy to explore the evolution of smoothing as the O₂ content in the process gas is increased. FIG. 15 illustrates various dry-etched samples oxidized at 450° C. with additions of 2000, 4000 and 7000 ppm O₂, respectively. In the illustrated examples, the etched sidewalls of the Al_{0.3}Ga_{0.7}As samples here are intentionally roughened by tuning the photolithography and dry etching recipes to obtain a sufficient degree of roughness for studying the capabilities of the oxidation smoothing. Oxidation time periods have been adjusted to yield a comparable amount of oxide growth. The normalized roughness reduction ratio is obtained by measuring the difference in amplitude between the sidewall surface roughness representative of the pre-oxidation roughness and the post-oxidation oxide/semiconductor interface (i.e., oxidation front) roughness, and then computing the ratio γ (Equation 3) of this difference to the total oxide thickness, making the assumption that this roughness difference increases linearly with the oxide growth.

$$γ = \frac{{α}_{i} - {α}_{0}}{t} \qquad Equation 3$$

In equation 3, αᵢ αₒ represent the sidewall roughness amplitude before and after oxidation, respectively. Additionally, variable t is the total thickness of the oxide. According to measurement of these roughness amplitudes and the oxide thicknesses from FIG. 15, the smoothing effect in a first sample 1505 that is oxidized with only 2000 ppm O₂ added is not very efficient (γ=0.095). However, noticeable improvement is achieved over the conventional oxidation without O₂, as was seen by the fourth sample 1320 of FIG. 13. By increasing the O₂ flow rate to 4000 and 7000 ppm, as shown in a second sample 1510 and a third sample 1515, roughness reduction efficiency is considerably improved to γ=0.242 and 0.239, respectively, demonstrating that the O₂ content is the principal parameter influencing the roughness reduction.

Two other temperatures are also examined to study the temperature dependence. As shown in a fourth sample 1520 and a fifth sample 1525 of FIG. 15, smoothing happens both at relatively low (400° C.) and high temperatures (500° C.). A greater roughness reduction ratio of γ=0.429 is achieved at 400° C. versus γ=0.212 at 500° C., which indicates that the oxidation smoothing is more effective at lower temperatures provided that the non-selective oxidation rates are sufficient. Such sufficient temperatures are typically above 350° C. Additionally, such temperatures typically result in less thermal damage to devices, although a longer oxidation time is needed to grow a sufficient amount of the oxide for the effective roughness reduction.

The roughness reduction ratio is likely to be varied to some extent with the degree of oxide growth if the oxidation rate is not linear, particularly because the roughness topography evolves during the oxidation process. The visual measurement from SEM images also introduces an unknown degree of error due to different imaging angles. The smoothing effect during the non-selective oxidation is exerted to a desirable degree only when the O₂ content reaches a certain value (>4000 ppm based on FIG. 15), and low temperatures appear to achieve a better smoothing result.

### Waveguide Fabrication

Both AlGaAs/GaAs rib and ridge waveguides have been successfully fabricated through conventional microelectronics processing procedures and non-selective oxidation. As schematically shown and mentioned above, HIC RWG fabrication starts with conventional wafer cleaning and then contact (or projection) photolithography followed by dry etching to define the waveguide stripes. The non-selective oxidation is then performed to laterally and partially oxidize the waveguide sidewall for roughness reduction. Skipping the metallization steps necessary only for the active device fabrication, the substrate of the sample is thinned down to around 200 μm in order to easily achieve optimized end-facets through cleaving. Clean and parallel end-facets are important to form a resonance cavity for the “Walker” Fabry-Perot (FP) loss measurement method discussed below.

FIG. 16 illustrates SEM images of an Al_{0.3}Ga_{0.7}As/GaAs rib structure 1605 with a rib height 1610 of approximately 0.8 μm. The structure 1605 is defined by BCl₃/Cl₂Ar RIE etching, followed by a non-selective oxidation at 450° C. for 25 minutes and including 7000 ppm O₂. An unexpected “bump” 1615 created by the imperfect dry etching is smoothed away with ˜200 nm of oxide growth, as is shown in the high-magnification SEM inset image 1620 of FIG. 16. The etched mesa leads to a small local effective index change due to the reduced Al_{0.3}Ga_{0.7}As thickness, which would provide weak lateral light-guiding region beneath the rib in an appropriate heterostructure (not employed in 1605).

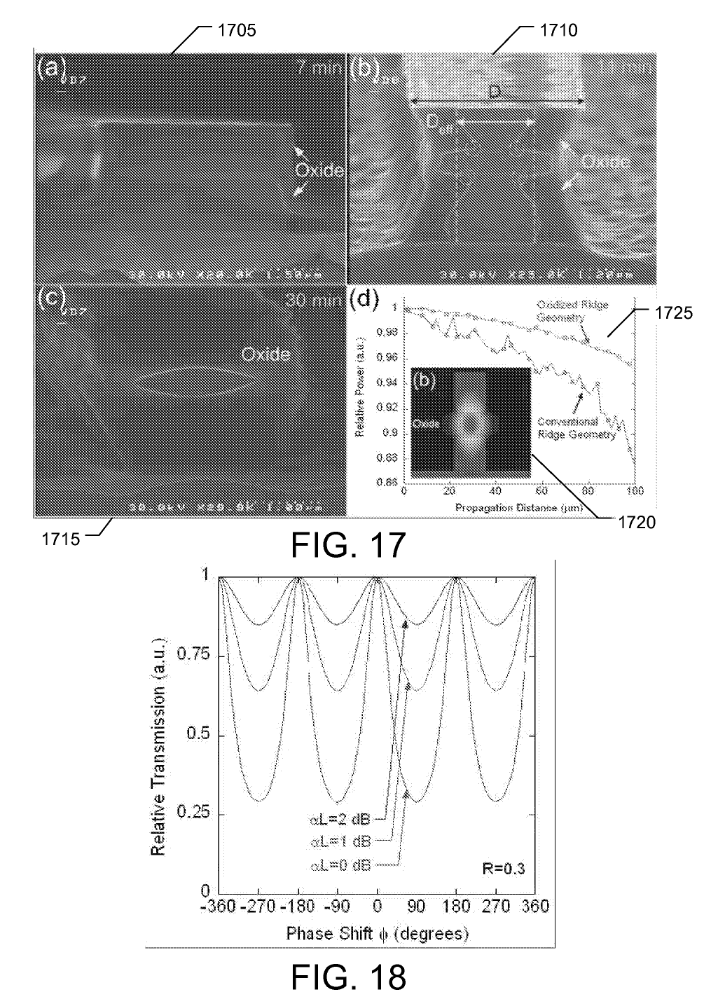

As discussed above, sidewall roughness is not necessarily a critical factor for waveguides with a low lateral index contrast. Therefore, AlGaAs/GaAs HIC RWGs are next fabricated on the waveguide heterostructure crystal on which the BPM simulations described above in FIGS. 6-8 were based. FIG. 17 illustrates non-selective oxidation of an Al_{0.4}Ga_{0.8}As/Al_{0.8}Ga_{0.2}As heterostructure at 450° C. with 7000 ppm O₂ for various periods of time. A first image 1705 illustrates a 7 minute oxidation time period, a second image 1710 illustrates an 11 minute oxidation time period, and a third image 1715 illustrates a 30 minute oxidation time period. Such oxidation time periods of 7, 11 and 30 minutes are chosen to demonstrate the evolution of waveguide geometry with the growth of the oxide. The sandwiched Al_{0.4}Ga_{0.6}As waveguide core layer is oxidized more slowly than Al_{0.8}Ga_{0.2}As upper and lower cladding layers, which results in the waveguide core becoming surrounded by the amorphous-phase oxide as the oxidation progresses. Eventually, a fiber-like HIC waveguide (completely confined by native oxide) is formed after oxidation for 30 minutes, as shown in the third image 1715 of FIG. 17, which illustrates a strong optical mode confinement in the horizontal direction and in the vertical direction. The large index step brings a large numerical aperture (Equation 4) and a corresponding large acceptance angle (Equation 5).

(NA)=\sqrt{n_{core}²−n_{cladding}²}=sin(θ) (Equation 4

2θ≈sin(n_{core}{square root over (2Δn))} Equation 5

The best candidate waveguide for studying the scattering loss reduction through non-selective oxidation should be the case shown as image two 1710 of FIG. 17, in which a considerable amount of oxide is formed on the sidewall of the low Al-ratio waveguide layer, but the oxide grown on the upper and lower claddings has not completely wrapped around the waveguide. As a result, a possible vertical current flow channel is still open for active devices. Furthermore, as shown in an inset 1720 of FIG. 17, a favorable optical mode cross-sectional image from a BPM simulation based on the actual fabricated dimensions (w_{core}=1.6 μm, w_{cladding}=0.9 μm) of the semiconductor (excluding the oxide parts) is shown. Compared with the BPM cross-sectional image of FIG. 7, the optical mode is further squeezed and pushed away from the sidewall because of the large index step localized at the junction (dash line circles of the second image 1710 in FIG. 17) of the semiconductor cladding and the oxide on the cladding sidewall and semiconductor core. As shown in the second image 1710 of FIG. 17, an effective ridge width D_{eff} exists somewhere between the semiconductor/oxide interfaces within the waveguide core and those within the upper and lower cladding layers. As D_{eff}<D, the single-mode cut off width of the physical waveguide stripe width D is extended by D-D_{eff}, reducing the challenges of narrow waveguide stripe definition by conventional lithography and dry etching. In other words, waveguides with an effective stripe width in the submicron regime (but a physical stripe width still in the micron range) can be achieved by conventional photolithography and dry etching plus a well-controlled non-selective oxidation process.

The HIC waveguide in this geometry is more immune to the rough interface because its optical mode is further removed from the semiconductor/oxide interface (see inset 1720) in comparison to that of the conventional waveguide with even vertical sidewalls from ridge top to base (e.g., an anisotropically dry-etched waveguide surrounded by CVD SiO₂, as in FIG. 7). A graph 1725 of FIG. 17 illustrates BPM simulations of relative optical power versus light propagation distance for both cases with the same intentionally-added wave-like sidewall roughness (σ=50 nm, Λ=1 μm). A reduction in the power loss of 62% through use of the oxidized ridge geometry is demonstrated by the simulations.

Unlike the SOI waveguide having a dimension that is typically comparable to the core diameter (˜8 μm) of single-mode glass optical fibers, the AlGaAs/GaAs HIC RWG's dimension is shifted towards the submicron regime for single-mode operation, leading to much more severe alignment tolerances. Fiber/semiconductor butt coupling, which is an approach for characterizing SOI waveguides, may not be practical here for AlGaAs/GaAs HIC RWG loss measurements. Instead, a lens or lens-tapered single-mode fiber (a special fiber with a conical output end shaped to focus the output light to a small spot) is used to couple the 1.55 μm wavelength laser beam into the waveguides. Furthermore, the common “cutback” method used in SOI waveguide loss measurements is not readily employed due to the inevitable problems associated with coupling reproducibility and waveguide end-facet reflections.

The Fabry-Perot (FP) method is a technique replying on a resonance cavity formed by cleaving the semiconductor along specific crystal planes. The finesse of the cavity is measured by varying the waveguide phase φ using thermal, wavelength, and/or electrooptic modulation tuning. The resonator transmission T is given by

T(ø)=(1−R)² e^{-αL}/[(1−r)²+4r sin^{2 ø]} Equation 6

In equation 6, R is the end-facet reflectivity, α and L are the propagation loss and length, respectively, r=Re^{-αL}, and φ is the phase which is varied during the measurement. FIG. 18 illustrates simulated Fabry-Perot fringes (transmission versus phase) for several values of αL and a typical semiconductor cleaved facet reflectivity R=0.3. On-chip losses of 0, 1, and 2 dB are shown in which transmission maxima and minima appear alternately, with a period of 180 degrees. The propagation loss value α can be extracted from the ratio of maximum and minimum transmission values, presented in Equation 7 below.

K−(Tₘₐₓ−Tₘᵢₙ)/(Tₘₐₓ+Tₘᵢₙ)=2r/(1+r²) Equation 7

In equation 7, K is the fringe contrast and yields r=Re^{-αL}. There is no dependence on the input coupling associated with the FP method as shown in Equations 6 and 7, thus problems with coupling reproducibility are avoided. For the most accurate loss measurement, multiple measurements of K with variable sample length L are acquired to first determine the waveguide reflectivity, which may differ somewhat from the simple Fresnel reflectance value given by R=(n−1)²/(n+1)².

Aside from the remarkable roughness reduction, particularly critical for HIC passive waveguides, the described partial non-selective oxidation on the dry etch-defined mesa can dramatically benefit active devices (e.g., laser diodes) through greater processing simplicity, improved insulating properties, improved passivating properties, improved scaling properties, and improved thermal properties of the oxides. The mode control provided by the oxide's low refractive index functions to yield improved device performance.

### Laser Diode Fabrication

The laser diodes utilized in this example are all made from a single quantum-well (SQW) graded-index separate-confinement heterostructure (GRINSCH) GaAs/AlGaAs/InAlGaAs wafer commercially available from EpiWorks®, Inc. The GRINSCH RWG laser is considered to be an attractive candidate structure to benefit from scattering loss reduction through the oxidation smoothing technique.

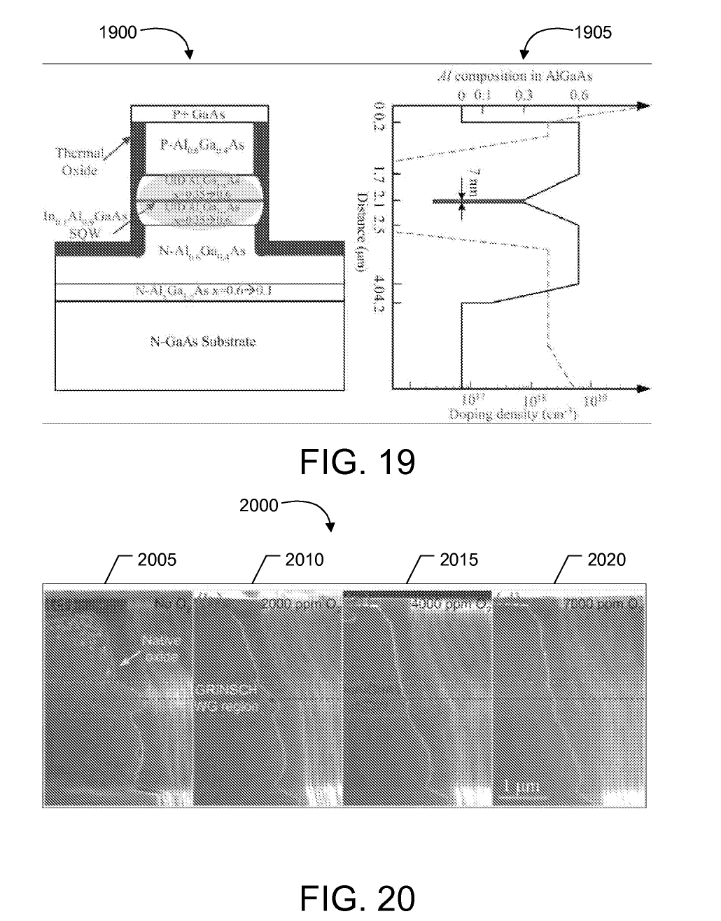

FIG. 19 illustrates a schematic of a typical AlGaAs/InAlGaAs/AlGaAs SQW GRINSCH RWG laser 1900 and a conduction band diagram 1905 showing a corresponding doping profile. In particular, FIG. 19 shows the laser schematic with an RIE-defined ridge structure and the corresponding crystal conduction band diagram and doping profile. Unlike the conventional double heterostructure (DH) laser whose core layer is only 200 nm thick or less, the graded core layer of this new crystal structure is of around 800 nm, typically called a broadened waveguide laser, which can drastically reduce the overlap between the optical mode and the highly doped regions of the cladding layers. This results in lower transmission loss and a significant improvement in the external differential quantum efficiency. Furthermore, the optimized GRINSCH offers maximum overlap of the optical mode with the gain in the active region, leading to a relatively low threshold current density and the capacity for considerably higher power operation where the operating current is greater than 10×Jₜₕ. As the waveguide core layer is fairly thick, scattering loss due to rough sidewalls replaces the free carrier absorption as the dominant transmission loss, which means cladding layers can be heavily doped to lower the series resistance and the oxidation smoothing can indeed be an effective technique to further reduce the waveguide transmission loss.

Several fabrication steps of an HIC oxide-confined RWG laser have been schematically highlighted in FIG. 3. The detailed processing procedures are listed below:

Wafer cleaning:
Soak in acetone and isopropyl alcohol (IPA), 5 min each.

SiNₓ deposition (PECVD):
t=200 nm, deposition rate˜150 A/min.

Contact photolithography:
PR spinning: HMDS+photoresist 1813, 2000 (10 sec)/4000 (30 sec) rpm;
Softbake (hot plate): 100° C., 1 min;
Exposure (Carl Suss MJB3 Aligner): Pₚₕₒₜₒₙ=130 mJ.

Developing:
40-60 sec in AZ 327 solution followed by blow drying.

Dry Etching (Plasma-Thermal RIE 790):
SiNₓ etching: CF₄/O₂ 25/5 sccm, P=30 mTorr, RF power=75 W; etch rate˜75 nm/min;
Ridge formation: BCl₃/Cl₂/Ar 10/2/8 sccm; P=20 mTorr, RF power=100 W; etch rate˜350-450 nm/min.

PR removal in acetone and IPA.

Non-selective oxidation:
N₂/H₂O/O₂ (4000-7000 ppm), T=450° C., ˜30 min (˜150 nm oxide growth).

SiNₓ removal Plasma-Thermal RIE 790:
CF₄/O₂ 25/5 sccm, P=30 mTorr, RF power=75 W; etch rate˜75 nm/min.

Isolation photolithography (Carl Suss MJB3 Aligner):
PR spinning: HMDS+PR 1813, 2000 (10 sec)/4000 (30 sec) rpm;
Softbake (hot plate): 90° C. 30 sec;
Exposure: 120 mJ photon energy.

P-metal deposition (E-beam evaporator FC1800#2):
Surface refresh: HCl:H₂O=1:4 10 sec, DI water rinse and blow dry;
Metal deposition: Ti/Au 200/3000 nm.

Lift-off in acetone+IPA.

N-side (substrate) lapping & polishing: wax (white) gluing sample with n-side up on a polishing holder, polishing sheets usage order 30 μm/9 μm/(mixing slurry) 1 μm, target thickness t˜100 m.

N-metal deposition (Varian thermal evaporator):
Surface refresh: HCl:H₂O=1:4 10 sec, DI water rinse and blow dry.
Metal deposition: AuGe/Ni/Au 650/120/3000 nm, evaporation rates˜5 A/sec/0.5 A/sec/8 A/sec.

Anneal (General-Air CVD): 40 sec @403° C. with N₂ flow.

LD bar cleaving:
wax (black) gluing sample with p-side up on an aluminum strip;
cleaving sample into bars ˜150-700 μm length;
bending aluminum strip based on a cylinder;
soaking bars off the aluminum strip in trichloroethane ˜30 min;
rinsing bars in acetone and IPA 5 min each followed by air dry.

One of the benefits of this example processing flow is to employ the non-selective oxidation, which yields a high-quality thermal native oxide to serve as an insulating dielectric, while simultaneously providing lateral optical confinement. The Al-ratio of the AlGaAs waveguide region in this work is not constant, but instead graded from 60% to 35% towards the InAlGaAs SQW, as shown in FIG. 19. The oxidation rate selectivity, which mainly depends on Al-ratio, results in slight variations in the oxidation front depth.

FIG. 20 shows SEM cross-section images 2000 for samples of AlGaAs/InAlGaAs/GaAs GRINSCH ridge geometry lasers oxidized laterally. The images illustrate oxidation (a) in ultra-high purity (UHP) N₂ at 450° C. for 100 min (2005), (b) with mixed 2000 ppm O₂+N₂ at 450° C. for 45 min (2010), (c) with mixed 4000 ppm O₂+N₂ at 450° C. for 40 min (2015) and (d) with mixed 7000 ppm O₂+N₂ at 450° C. for 35 min (2020), respectively. Oxidation times were adjusted to obtain a native oxide of approximately 400 nm thickness in the x=0.6 AlₓGa₁₋ₓAs cladding layers for each case to provide the best comparison. A noticeable difference clearly exhibited in the SEM images 2000 above is that the oxide growth in the GRINSCH waveguide region is catching-up to that in the upper and lower cladding layers as the O₂ content in the reaction gases increase. For case (a) 2005 of the conventional wet oxidation, a fairly long oxidation time (100 min) is required to achieve the same thickness cladding layer oxide as the non-selective (O₂-added) oxidations achieves in 35-45 min. The oxidation rate selectivity for different Al-ratio AlGaAs is also shown by the “protruded” oxidation front in the waveguide region for case (a) 2005. Here, the minimum thickness oxide (˜160 nm) is grown around the center of waveguide region (i.e. InAlGaAs QW), making it the region of weakest carrier and optical lateral confinement. The oxide is also formed directly beneath the GaAs cap layer in case (a) 2005 due to enhanced oxidant lateral diffusion along the GaAs/AlGaAs interface, which could ultimately block the injected current needed for laser operation.

In contrast, the oxidation front in the waveguide region becomes progressively more uniform with increasing O₂ content due to the enhancement of the oxidation rate for low Al-ratio AlGaAs and the lateral diffusion of oxidant through the oxide in the cladding layers (see images 2010, 2015, and 2020). A similar thickness of oxides in the waveguide and cladding regions is observed when 4000-7000 ppm O₂ is added into the wet oxidation stream, giving optimum lateral dimension control and electrical confinement. Therefore, the laser diodes fabricated herein are all oxidized with the addition of either 4000 ppm or 7000 ppm O₂.

Two types of Fabry-Perot (FP) HIC RWG laser diodes are fabricated and characterized below, one with a straight FP resonance cavity 2105 and the other one with a half racetrack ring geometry FP resonance cavity 2110 (referred to herein as a half-ring), shown schematically in FIG. 21. Straight laser diodes with stripe widths ranging from 5-150 μm and half-ring laser diodes with curvatures ranging from 10-320 μm are characterized and separately discussed below with different device performance emphasis.

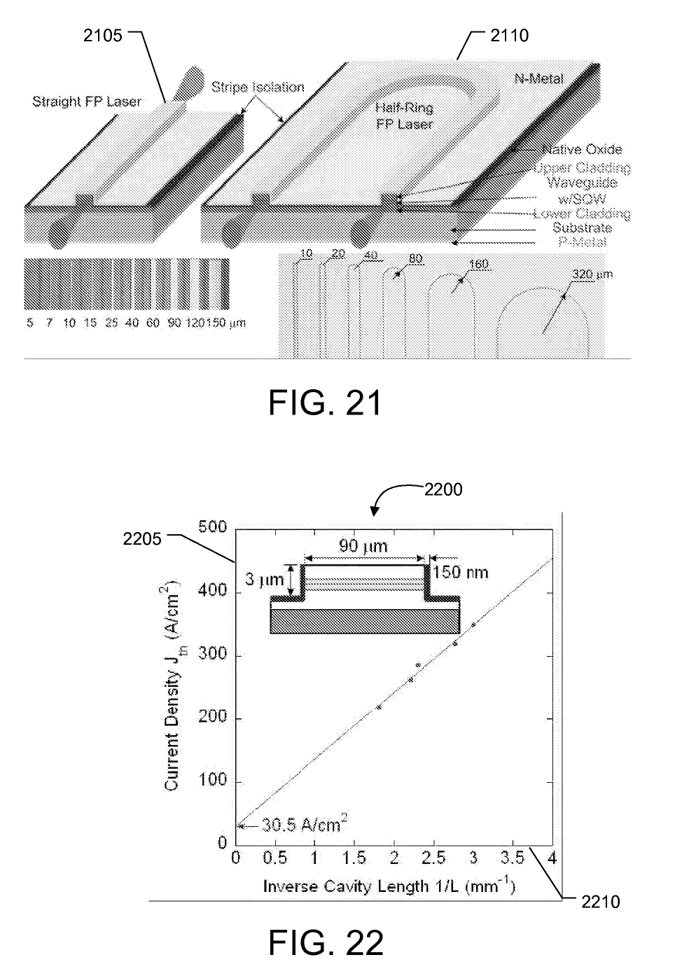

The broad-area (BA) threshold current density is a useful figure of merit that is, in part, indicative of the “quality” of the constituent semiconductor material and heterostructure design. A BA laser with a stripe width w>50 μm typically does not employ any scheme for current confinement, or suffer from scattering loss from sidewall roughness. Contact resistance is also negligible due to the large contact area (w×L). FIG. 22 illustrates a plot 2200 of BA laser threshold current density 2205 versus inverse laser cavity length 1/L 2210. In particular, FIG. 22 shows the relationship of threshold current density Jₜₕ of the BA lasers with a 90 μm stripe width to the inverse laser cavity length. A very low current density of Jₒ=30.5 A/cm² is found by extrapolating to the point of 1/L=0 (i.e. L→∞), where the effect of mirror losses vanish, which indicates the high quality of the laser material used in this example. BA lasers also present a good reference for narrow stripe lasers because the deleterious effects of surface states and sidewall roughness (important for narrow stripe lasers) do not typically play a significant role in BA lasers.

### Laser Characterization

The first measurement typically done on a laser diode is that of optical output power (i.e., output light intensity) as a function of input current, which presents the “LI” characteristic of a laser diode. LI measurements are often accompanied by a current-voltage (IV) measurement, showing an electrical exponential turn-on characteristic of a diode. The IV characteristic is also helpful to track possible problems, such as high series or contact resistance, testing stage-introduced error, etc.

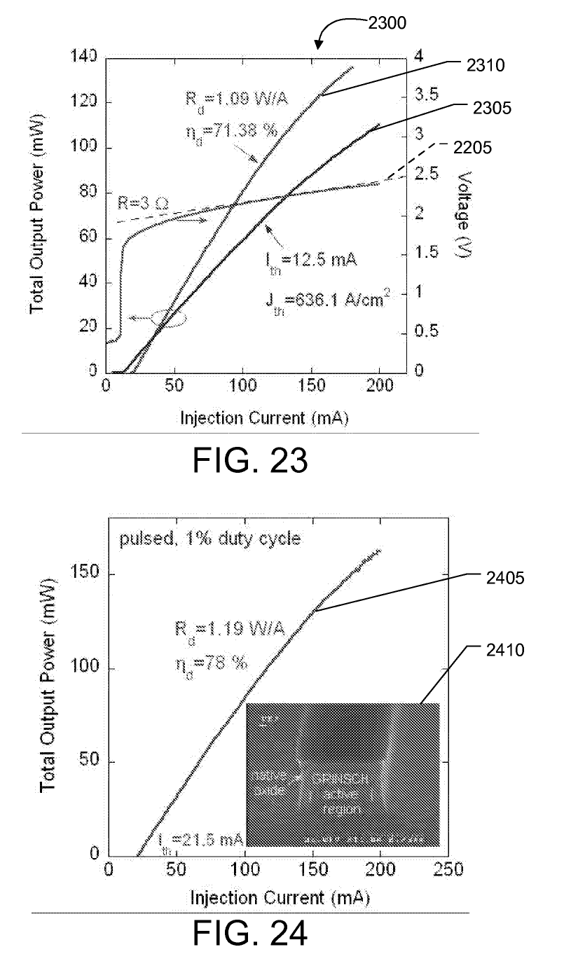

FIG. 23 illustrates a plot 2300 showing LI characteristics and IV characteristics for wide native oxide-confined GRINSCH HIC RWG straight lasers. In particular, data for native oxide-confined straight lasers with a narrow stripe of 5 μm exhibit a good kink-free laser performance under pulsed current injection (1% duty cycle). A first laser curve 2305 having the lowest threshold current density of Jₜₕ=636.1 A/cm² (Iₜₕ=12.5 mA) is obtained though the slope efficiency R_{d} (i.e., differential responsivity), is relatively low (R_{d}=0.7 W/A). A second laser curve 2310 has a slightly higher threshold current Iₜₕ=20 mA (Jₜₕ=1108 A/cm²) and demonstrates a high slope efficiency of R_{d}=1.09 W/A, which corresponds to an external differential quantum efficiency of η_{d}=71.38% at a lasing wavelength of λ=812 nm according to a relationship of η_{d}=R_{d}λ/1.24 (λ in unit of micron). The most straightforward efficiency parameter, the overall efficiency (i.e. wall-plug efficiency) of 35% at I=150 mA, is obtained by taking the ratio of the output optical power to the product of injection current and the corresponding voltage. The output power of all LI curves described herein is the total 2-facet output power obtained by doubling the measured single-facet power, noting the assumption that equal light emission is valid due to the absence of facet coatings.

The slope of the IV curve 2315 shows a good diode operation with a total resistance (diode resistance+testing stage resistance) of 3 Ω, indicating a good ohmic contact at both a p-side and an n-side.

Another example laser, a curve 2405 of which is shown in FIG. 24, includes a stripe width of 7 μm and demonstrates an even higher slope efficiency of R_{d}=1.19 W/A, which corresponds to a 78% external differential quantum efficiency. The inset 2410 in FIG. 24 is a SEM cross-sectional image with a w=3.9 μm HIC RWG structure for half-ring lasers (with 200 nm-thick PECVD SiNₓ mask layer on the ridge top) after etching and a 30 min, 450° C. nonselective oxidation. Comparably high efficiency for both 5 and 7 μm wide lasers indicates both a low non-radiative recombination and a low scattering loss resulting from native oxide passivation.

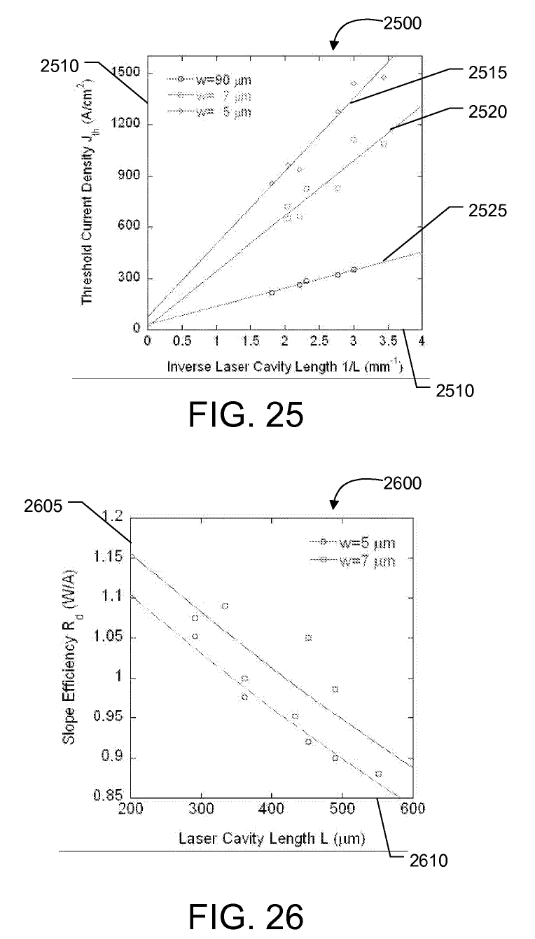

FIG. 25 illustrates a plot 2500 of laser threshold current density 2505 versus inverse laser cavity length 2510 showing curves for 5 μm lasers 2515, 7 μm lasers 2520, and 90 μm lasers 2525. FIG. 26 illustrates a plot 2600 of slope efficiency 2605 versus laser cavity length 2610 for 5 μm lasers 2615 and 7 μm lasers 2620. FIGS. 25 and 26 summarize the relationships of laser average threshold current density and slope efficiency to the laser cavity length. Compared with BA lasers, narrow stripe lasers show a higher threshold current density due to inevitably higher non-radiative recombination, more thermal effects, more scattering loss, and higher contact resistance. At 1/L=2.5 mm⁻¹ (i.e., L=500 μm) in FIG. 25, threshold current density values of 5 μm and 7 μm wide lasers are only 2.7× and 3.8× higher, respectively, than that of BA lasers whose area (linearly proportional to contact resistance) is 12.9× and 18× larger than two narrow stripe lasers. Such results may be attributed to a good surface passivation (discussed in more detail below), good thermal conductivity, and low scattering loss, all of which come from the high-quality native oxide.

With the increasing laser cavity length, the threshold current density decreases due to the decreasing influence of the length-distributed mirror loss, inversely proportional to the cavity length and given by Equation 8.

$${α}_{m} = \frac{1}{2 L} ln \frac{1}{{R}_{1} {R}_{2}} \qquad Equation 8$$

In equation 8, L is the cavity length, and R₁ and R₂ refer to the reflection coefficients of two end facets. When the laser cavity is infinitely long (1/L=0), both BA and narrow stripe lasers reach a comparable current density (<100 A/cm²).

In contrast, laser slope efficiency R_{d} follows an opposite trend, decreasing with increasing cavity length, as shown in FIG. 26. A laser with a short cavity has to inject many more electron-hole pairs before the gain overcomes the total loss α=αₛ+αₘ (i.e., higher threshold current), achieving stimulated emission because of the higher mirror loss αₘ. However, the mirror loss is not like other losses αₛ associated with material absorption and scattering from the optical inhomogeneities where power is lost inside the cavity, but is due to a power escaping out of the laser facets. As this power is essentially the optical output power, the external quantum efficiency values are higher. In other words, by driving with the same amount of current (>Iₜₕ), a laser with a short cavity emits more power, but has to sacrifice for maintaining the positive feedback the cost of a higher current density. In short, the selection of the optimal laser bar length depends on whether the specific application prefers a low threshold current density or a high efficiency.

In another example, the emission wavelength of GaAs-based diode lasers may be extended to the 1.3 and 1.55 μm fiber-optic telecommunications bands through the incorporation of dilute amounts of nitrogen into an active region. Low-threshold current InGaAsN quantum well ridge waveguide (RWG) lasers fabricated by pulsed anodic oxidization may include an AlₓGa₁₋ₓAs (x=0-0.5) upper cladding layer. As discussed above, example wet oxidation rates of low Al content AlₓGa₁₋ₓAs (x<0.6) are greatly enhanced (and the rate selectivity to Al content reduced) via the controlled addition of trace amounts of O₂ to a conventional wet (N₂+H₂O) thermal oxidation process. Based on a self aligned, deeply etched plus modified oxidation process (referred to as “nonselective” oxidation), example device-quality thermal oxides may be formed not only in Al_{0.65}Ga_{0.35}As cladding layers, but also directly on the GaAs waveguide and GaAsP/InGaAsN active region layers. With the strong optical confinement provided by the high index contrast (HIC) between the semiconductor and oxide, and the complete elimination of current spreading by the deeply-etched ridge, enhanced laser performance with stable spatial-mode behavior may be achieved. Relative to conventional shallow-etched index-guided RWG lasers fabricated out of the same material, example HIC RWG narrow-stripe lasers described herein show approximately 2 times lower lasing threshold current densities with kink-free operation. The HIC structure is especially promising for ring-resonators and curved waveguides useful for advanced integrated photonic devices, as discussed in further detail below.

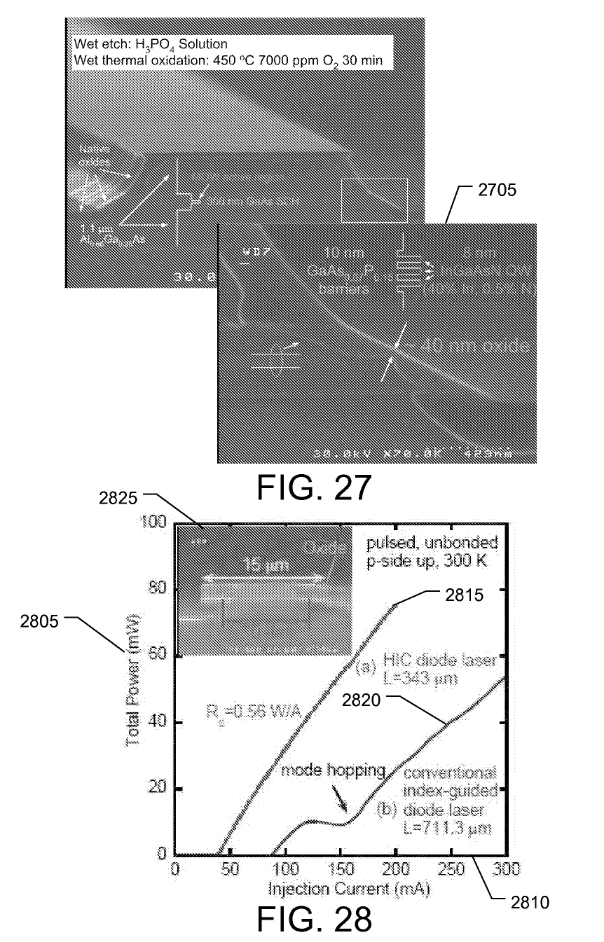

In the illustrated examples, deeply etched HIC-type and conventional index guided RWG laser diodes are fabricated in a λ˜1250-1270 nm large optical cavity, multiple quantum well (MQW) heterostructure. Three example 8 nm InGaAsN (In=40%, N=0.5%) quantum wells are alternately embedded in four 10 nm GaAs_{0.67}P_{0.15} barriers, which are sandwiched in a 300 nm GaAs separate confinement heterostructure (SCH) formed with 1.1 μm Al_{0.65}Ga_{0.35}As cladding layers. Prior to example RWG laser fabrication, wet-etched stripes are used to study the non-selective oxidation of the GaAsP/InGaAsN MQW active region. FIG. 27 shows a scanning electron microscope (SEM) image of an example 7 μm wide stripe-masked ridge that is wet etched in a H₃PO₄:H₂O₂:H₂O solution for 90 sec and then wet oxidized at 450° C. with the addition of 7000 ppm O₂ (relative to N₂ carrier gas). The higher magnification SEM image inset 2705 clearly demonstrates greater-than or equal to 40 nm oxide growth in an active region with 115 nm of oxide formed in a GaAs waveguide core layer. In the illustrated example, laser fabrication starts from a 200 nm thick PECVD SiNₓ mask layer deposition, followed by contact photolithography to pattern straight stripes. Then the example ridge is dry-etched via reactive ion etching (RIE) either into the lower AlGaAs cladding layer to expose both waveguide and active region, or stopping in the upper AlGaAs cladding layer. Non-selective wet thermal oxidation at 450° C. with the addition of 7000 ppm O₂ may be subsequently applied to both deeply-etched and shallow-etched samples for 2 hours or 30 min, respectively. Approximately 2.93 and 2.5 μm of oxide may be grown on the AlGaAs cladding layers and GaAs waveguide, respectively, for the deeply etched sample. Following oxidation, the SiNₓ mask may be selectively removed by RIE. After standard lapping, polishing, metalization and cleaving, unbonded devices may be probe tested (unction side up) under pulsed conditions (0.5 μS pulse, 1% duty cycle) at 300 K using any appropriate laser test system, such as a Keithley® Model 2520 laser test system. Device facets may be uncoated and example total output power is plotted below (see FIG. 28) is calculated by doubling the measured single facet outputs.

For broad-area lasers fabricated to study material qualities, example HIC structure devices described herein have consistently lower threshold current densities than conventional shallow-etched RWG devices, demonstrating that the elimination of current spreading has a significant impact even with wide emitter stripes. For example, at L=1 mm cavity lengths, data (not shown) indicates threshold current densities on HIC broad-area lasers (w=85 μm) of 502 A/cm² compared to 597.5 A/cm² for conventional broad-area devices (w=90 μm), a 16% reduction.

In narrow-stripe lasers, where optical and current confinement may become more critical, a much more significant performance advantage may be achieved by example HIC structures described herein. FIG. 28 shows typical output power 2805 vs. current 2810 characteristics for (a) HIC (see curve 2815) and (b) conventional RWG lasers (see curve 2820) with w=10 μm stripe widths. Due to both weak optical confinement and carrier leakage via current spreading, it is well known that mode hopping can frequently occur in weakly-guided narrow-stripe lasers, as we observe for most conventional devices. In contrast, the example HIC RWG laser of FIG. 28 (curve 2815) shows kink-free operation, which suggests stable spatial-mode behavior. An inset SEM cross-section image 2825 shows an example w=10 μm (at active region) HIC RWG device, with a vertical channel formed after non-selective oxidation to eliminate current spreading and provide strong index guiding. As shown in FIG. 28 (curve 2815), low-threshold current (Iₜₕ=39.1 mA) and high slope efficiency (R_{d}=0.56 W/A) operation is obtained without visible mode hopping.

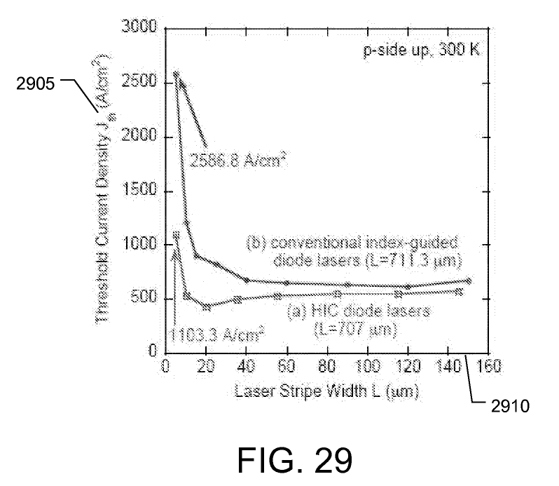

The threshold current density differences of the two devices in FIG. 28 are less than might be expected due to the higher distributed loss of the shorter cavity example HIC device. Two bars containing devices of varying stripe width, but comparable cavity length, are selected to further study current spreading effects. Threshold current density 2905 vs. laser stripe width 2910 is plotted in FIG. 29, showing that the current spreading present in conventional, shallow-etched RWG devices dramatically increases the threshold current density with decreasing stripe width. A high threshold current density of 2586.8 A/cm² for the w=5 μm conventional device is more than 2.3 times higher than that of an example HIC RWG device with the same active stripe width (1103.3 A/cm²). Such threshold current density of the w=5 μm HIC structure laser is approximately 2× higher than that of broad-area (e.g., w>90 μm) HIC devices, indicating not only excellent optical and electrical confinement, but also negligible sidewall non-radiative recombination even though the native oxide grown in direct contact with the active layer.

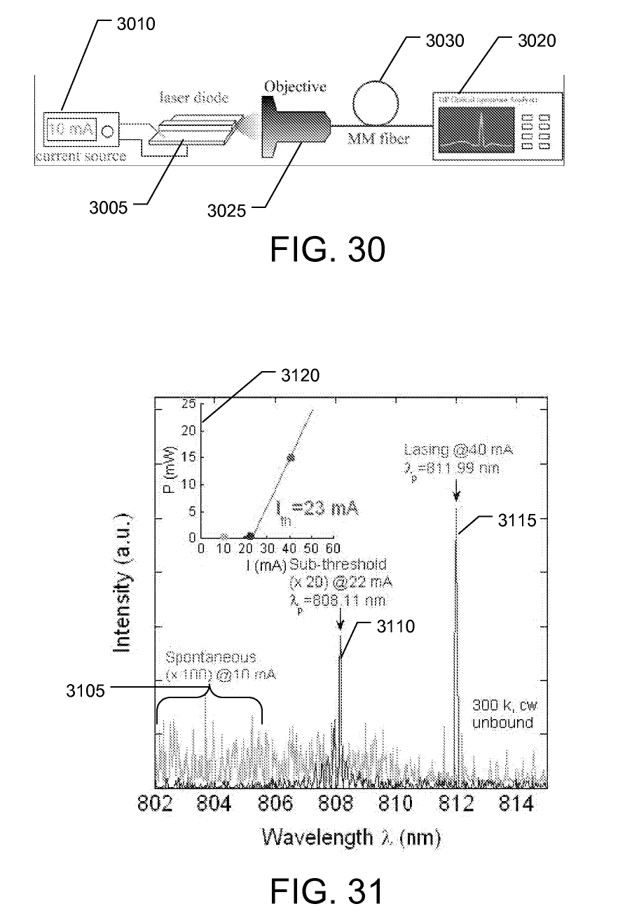

Excellent spectral properties make lasers superior to other light-emitting devices for many applications requiring coherent radiation. A number of important laser operating parameters (wavelength, mode-spacing, etc.) can be determined through spectral measurements, which are slightly more involved than power measurements. As shown schematically in FIG. 30, an HIC oxide-confined straight LD bar 3005 is set on a probing stage and unbonded with the p-side facing up (at room temperature). A narrow stripe LD with ridge width of 5 μm and cavity length of 433 μm is biased with a current source 3010 and emitted light 3015 is coupled into an HP 70952B optical spectrum analyzer (OSA) 3020 via a microscope objective 3025 and multi-mode (MM) optical fiber 3030.

FIG. 31 illustrates three spectra of an HIC straight RWG LD, a first spectra 3105 measured at a 10 mA, a second spectra 3110 measured at 22 mA, and a third spectra 3115 measured at 40 mA. FIG. 31 also includes an inset 3120 showing an LI plot of a measured LD with a 23 mA threshold current. The three spectra shown in FIG. 31 are measured for a laser in different regimes: spontaneous emission, near-threshold emission, and lasing at well above threshold which is Iₜₕ=23 mA in the illustrated example. The transition from one to the other clearly demonstrates the onset of lasing. Spontaneous emission results when the laser is operated well below its lasing threshold (I=10 mA), which leads to a broad emission peak characteristic of a light emitting diode (LED), as shown by the first noisy spectra 3105. The near-threshold spectrum measurement 3110 is taken at a fraction of one mA below the threshold current. The noticeable spectral narrowing is attributed to the domination of low-order waveguide modes due to their low loss. The spectrum 14 mA above the threshold (i.e., I=40 mA), as shown by the third spectra 3115, indicates a considerably narrower single longitudinal mode of width 0.09 nm (limited by the spectrum analyzer resolution of 0.08 nm) and is about a factor of 100 times more intense because all of the gain is restricted to the one mode with the lowest threshold gain and the spontaneous emission is drastically reduced. The peak wavelengths in the three regimes show a red shift (˜803.2 nm→808.1 nm→811.99 nm) owing to heating during continuous wave (CW) operation of those unbonded devices (i.e., not soldered to a heatsink). The lasing wavelength red shift is predominantly due to a local bandgap narrowing in active region.

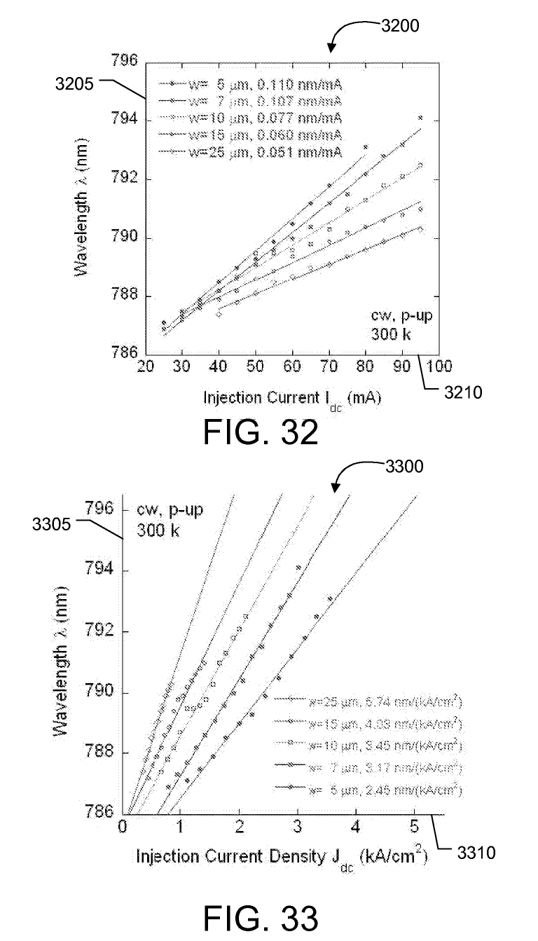

FIG. 32 illustrates a plot 3200 of lasing wavelength 3205 versus CW injection current 3210 for lasers having varying stripe widths. In the illustrated example, the wavelength shift is shown with the increasing injection current (>Iₜₕ) for lasers of varying stripe width. The lasing wavelength shift is measured under true CW operation at room temperature when lasers are unbonded and p-side up (without any heatsink). Wavelength increases linearly with injection current, i.e., input power IV as V is relatively constant over this current range, indicating that the temperature is linearly dependent on input power. As shown in the plot 3200 of FIG. 32, the wavelength shifts faster for narrower stripe lasers, which means narrower stripe laser experiences a higher cavity temperature with a poor heat dissipation mechanism.

FIG. 33 illustrates a plot 3300 of lasing wavelength 3305 versus injection current density at room temperature for lasers having varying stripe widths. In the illustrated example of FIG. 33, the same data points are plotted as a function of current density as were shown in FIG. 32, but a different result emerges. In particular, for an unbonded, p-side up oxide-confined RWG laser, heat in the semiconductor can be dissipated though the top p-side and bottom n-side metal contacts and the oxide on the sidewall and base. Due to the vicinity to the quantum well active region, the metal contact on the p-side rather than n-side can more effectively dissipate the heat built up in the active region. Therefore, the effective area for heat dissipation is the top contact area (L×w) plus oxide area (2×L×h, 2 sidewalls) where h is the ridge height. For the lasers fabricated on the same bar with same ridge height but different stripe widths, the oxide area is identical in each laser. As a result, when the laser stripe width (i.e. metal contact stripe width) gets larger, the ratio of the oxide area to the whole area for heat dissipation decreases. As the cavity temperature is proportional to the laser current density, a wider stripe laser (such as w=25 μm) demonstrates a larger wavelength shift per unit current density [5.74 nm/(kA/cm²)], which indicates a poorer heat dissipation capacity. Therefore, the oxide may contribute to the efficient dissipation of heat away from the cavity because a narrow laser with a large ratio of oxide area to the whole area exhibits a smaller wavelength shift per unit current density. Less than a 10 nm red shift when the injection current goes from 25 to 95 mA also illustrates a good thermal property for these devices.

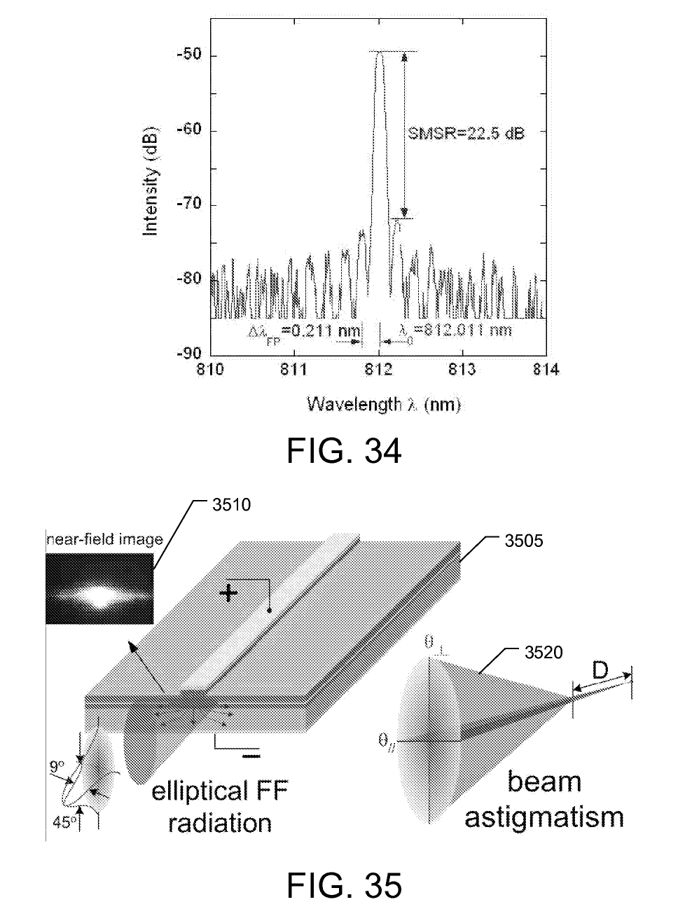

FIG. 34 illustrates a spectrum of an HIC straight RWG LD measured directly above a threshold of 27 mA. In the illustrated example spectrum of FIG. 34, I=40 mA with a logarithmic vertical axis calibrated in dB shows a center wavelength of λ₀=812.011 nm, a high side-mode suppression ratio (SMSR) of 22.5 dB, and a mode-spacing of Δλ_{FP}=0.211 nm. Compared with the linear scale spectrum shown in FIG. 31, the center wavelength is shifted to 812.011 nm (a 0.021 nm increase) at the same current injection due to slight further heating. A 22.5 dB SMSR demonstrates that the next highest mode is below the laser peak by a factor of ˜180, which demonstrates a spectrally single longitudinal mode laser operation.

The mode-spacing Δλ_{FP} is another important parameter for FP lasers because it allows the user to predict certain aspects of laser spectral behavior, such as the occurrence of mode hops. The mode-spacing can be theoretically determined by taking the differential of the resonant phase matching condition, as shown in Equation 9.

λ₀=2nL/i (for i=1, 2, 3 . . . ) Equation 9

In equation 9, L is cavity length and n is the refractive index of core material.

λ₀di+idλ₀=2Ldn Equation 10

In equation 10, L is assumed constant. For one example mode step, di=1,

$$i + \frac{λ}{d {λ}_{0}} = 2 L \frac{d n}{d {λ}_{0}} \qquad Equation 11$$

Plugging equation 11 into equation 10 yields

$$d {λ}_{0} = \frac{{λ}_{0}^{2}}{2 Ln - 2 L {λ}_{0} \frac{d n}{d {λ}_{0}}} ≡ Δ {λ}_{FP} \qquad Equation 12$$

In equation

$$12 , \frac{d n}{d {λ}_{0}}$$

represents the dispersion of the core material and is negligible in general cases. As a result, equation 12 simplifies to

$$\begin{matrix}Δ {λ}_{FP} = \frac{{λ}_{0}^{2}}{2 Ln} \\ or & Equation 13 \\ Δ {v}_{FP} = \frac{c}{{λ}_{0}^{2}} Δ {λ}_{FP} & Equation 14\end{matrix}$$

By plugging λ₀=812.011 nm, L=433 μm, and average n=3.42 for InAlGaAs into equation 13, the mode-spacing of this measured HIC RWG LD is obtained to be Δλ_{FP}=0.223 nm (corresponding to Δv_{FP}=101.3 GHz), within 5% of the measured data in FIG. 34.

The light from a laser diode will ultimately need to be coupled into some optical elements, such as a lens, a fiber, a waveguide, a beam splitter, etc. Optimization of optical coupling will generally result in system performance improvements. Fundamentally, one of the most important parameters for evaluating the emission property of a laser diode is, in many cases, the far-field intensity profile. The far-field patterns in the directions parallel and perpendicular to the junction plane indicate the angular intensity distribution of the laser mode, which is the most critical factor for the coupling efficiency between the semiconductor laser and other optical components.

FIG. 35 illustrates schematics of a conventional edge-emitting laser diode, showing two pitfalls in laser diode applications. A first schematic 3505 illustrates the pitfall of asymmetric near-filed patterns leading to elliptical far-field radiation, as shown in an inset 3510. A second schematic 3520 illustrates the pitfall of beam astigmatism. For an edge-emitting laser with an asymmetric aperture typically 200-500 nm thick (in the transverse direction) and 2-5 μm wide (in the lateral direction), the near-field pattern shown in the inset 3510 at the output face is also asymmetric, resulting in a highly elliptical far-field intensity distribution. This can be understood in terms of diffraction of light. Furthermore, this beam asymmetry is also a consequence of the lack of sufficient methods to provide comparable lateral confinement of photons and carriers. In other words, the unavoidable current spreading effect in conventional shallow-etched RWG lasers makes the optical mode field more extended laterally, giving an asymmetric output beam as shown in FIG. 35. Typical index-guided lasers have output beam ellipticity aspect ratios of ≧4, with full width half maximum (FWHM) angles of ≧40 degrees in the perpendicular axis versus 10 degrees in the parallel axis.

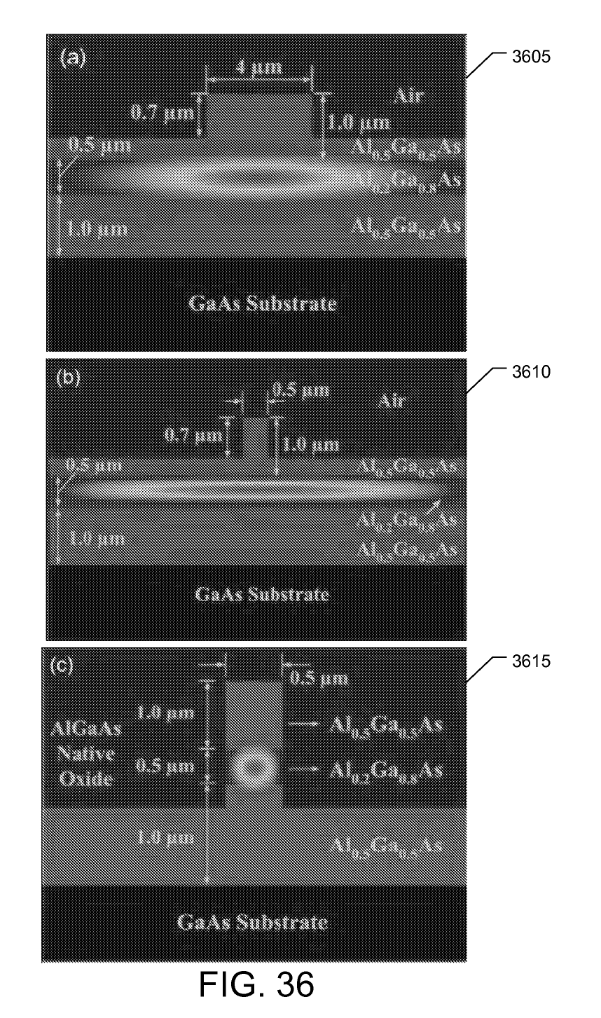

FIG. 36 illustrates various waveguide structures. A first conventional waveguide structure 3605 shows an asymmetric mode profile based on the BPM simulation of a passive AlGaAs rib waveguide structure (w=4 μm) commonly employed for a conventional shallow-etched RWG laser. Due to the compressed horizontal scale in the top of the first conventional waveguide structure 3605, the asymmetry for this representative conventional design is much worse (˜27:1) than it appears. Reducing the rib waveguide width actually inversely increases the lateral dimension of the optical mode due to a loss of effective optical confinement as shown in a second conventional waveguide structure 3610. When applying the same structures to laser diodes, current spreading will further worsen the conventional cases shown in the first and second conventional waveguide structures 3605, 3610. However, by using a slightly broadened active region and squeezing the mode laterally with the low index (n˜1.6) native oxide, a circular mode (1:1 aspect) can be obtained in an HIC RWG, as shown in a native oxide-defined AlGaAs/GaAs passive WG structure 3615. The new laser structure substantially eliminates the lateral current spreading and simultaneously traps the optical mode between the oxide shield, which solves the long-term problem of asymmetric beams.

Elimination of the current spreading improves power conversion efficiency and may be particularly beneficial in an array of HIC RWG laser stripes (e.g., a laser diode bar). Conventional laser diode bars typically have up to 40 individual emitters of 80-100 micron widths (each) that are spaced on 200-500 micron centers. Such bars are a large production item for pump diodes in diode-pumped solid state laser applications. However, unlike the conventional laser diode bars, the HIC RWG structure suppresses higher-order modes, current spreading, beam filamentation, and/or spatial hole burning effects that may degrade beam quality and limit maximum laser output power.

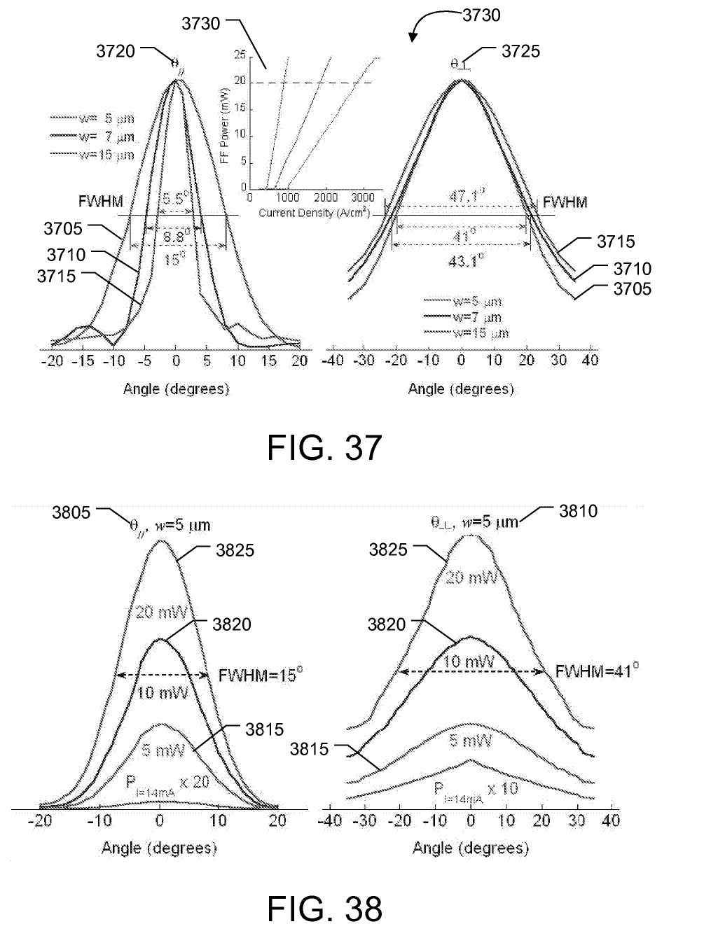

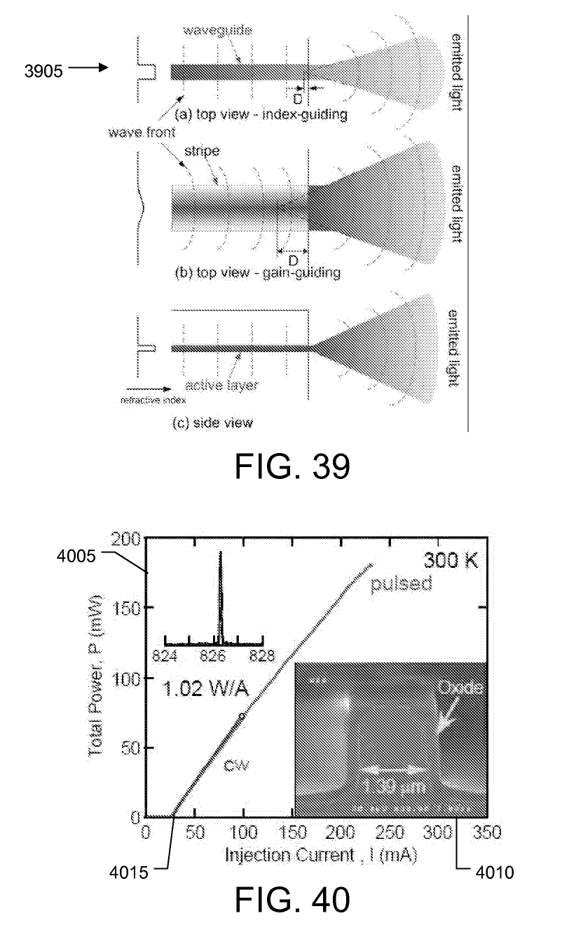

To experimentally explore the possibility of achieving a circularly symmetric optical mode, a far-field measurement is conducted in the directions parallel and perpendicular to the junction plane. FIG. 37 illustrates far-field patterns for deep-etched oxide-confined RWG lasers having stripe widths of 5 (curve 3705), 7 (curve 3710), and 15 μm (curve 3715). Lasers are operated under true CW mode with an output power of 20 mW. As the laser lateral dimension shrinks (15 μm→7 μm→5 μm), its full-width at half maximum (FWHM) divergence angle θ_{//} (plot 3720) parallel to the junction plane increases due to light diffraction (5.5°→8.8°→15°). The divergence increase apparently is not linear but accelerates as stripe width gets smaller and smaller. A small, opposite dependence of divergence angle in the direction perpendicular to the junction plane on laser stripe width is also observed (plot 3725). While the vertical dimension (i.e. thickness of waveguide core layer) is not changed, though θ_{□} (3725) does not change as dramatically as the lateral divergence angle θ_{//} (3720), the divergence angle θ_{□} does decrease slightly from 47.1° to 43.1° to 41° as the stripe width is reduced from 15 μm to 7 μm to 5 μm. The variation of θ_{□} is more dependent on the waveguide confinement factor Γ which can be defined as Equation 15 below.

Γ=2π²( n̅₂̅²̅− n̅₁̅²̅)d²/λ₀² Equation 15

In equation 15, n̅₂̅ and n̅₁̅ represent the real parts of the refractive index for the active layer and cladding, d is the thickness of the active layer and λ₀ is the free-space wavelength. The far-field patterns in FIG. 37 present angle divergence when three lasers all reach 20 mW of front facet power under CW mode operation without a heatsink. As a result, heat can easily build up inside the resonance cavity (i.e., the waveguide region here) but in a different degree for lasers with stripe widths of 5, 7 and 15 μm. In view of the three lasers being on the same bar, narrower devices consume more injection current to compensate the losses from the non-radiative recombination and scattering, which results in a higher current density necessary to reach 20 mW, as shown by inset 3730 of FIG. 37. Therefore, the narrower stripe lasers experience more heat building up than the wider ones because temperature is proportional to the current density. Material refractive index (real part) always reduces when material temperature is rising, which indicates the waveguide index n̅₂̅ of the 5 μm laser is smaller than that of the 15 μm laser.

On the other hand, the cladding index n̅₁̅ does not vary too much because heat generation typically occurs only in the active region (within the waveguide) as non-radiative recombination where Joule (I²R) heating is greater where the doping is lowest. Similarly, non-recombination processes are most likely forward due to bipolar activity. As a result, Γ_{x=5 μm}<Γ_{x=7 μm}<Γ_{x=15 μm}, leading to a consequence that the actual vertical size of the optical mode for for w=5 μm laser is slightly bigger than the other two lasers. Furthermore, the power area density at the laser emission facet for w=5 laser is the highest because the fixed output power (20 mW) is distributed over the smallest area (w×L). This high power area density further enhances the local temperature at the laser facet and consequently further reduces the confinement factor. Due to the diffraction effect of θ_{□}˜1/d, vertical divergence angle θ_{□} for w=5 μm laser is the smallest among the three lasers measured. Following the opposite trend of divergence angles θ_{//} and θ_{□} to the laser stripe width, achieving a circularly symmetric mode (θ_{//}=θ_{□}) appears very feasible in a laser with a stripe width smaller than 5 μm.

Moreover, the laser diode with w=5 μm demonstrates a smooth far-field single lobe in the directions both parallel and perpendicular to the junction plane at different output power levels, thereby demonstrating spatial single-mode operation. FIG. 38 illustrates far-field patterns parallel to the junction plane 3805 and perpendicular to the junction plane 3810. Output peak powers are taken well below threshold current (i.e., 14 mA) for a 5 mW laser 3815, a 10mW laser 3820, and a 20 mW laser 3825. Output power at I=14 mA is multiplied by factors of 20 and 10 for θ_{//} and θ_{□}, respectively, to make the curves visible. The BPM simulation shows that the higher-order mode of the same waveguide structure is cut-off around w=1 μm, thus a passive RWG with w=5 μm is not supposed to be in the single-mode regime. However, the single-mode operation for HIC active waveguides, such as laser diodes, will also largely be affected by mode competition where the fundamental mode with the lowest loss reaches stimulated emission first and consumes most of the carriers, thereby suppressing the lasing probability for higher-order transverse (waveguide) modes. These devices are likely to require a large amount of injection current which may damage the device before the higher-order modes start lasing.

Beam astigmatism, as shown in FIG. 35, is another potential disadvantage of edge-emitting laser diodes, particularly those with gain-guided designs, in which guiding depends on a nonlinear index change caused by a nonlinear gain profile. FIG. 38 illustrates beam waist and astigmatism in conventional index-guided and gain guided lasers. Because the beam dimension is defined by properties in the plane of the junction that differ from those in the plane perpendicular to the junction, the beam appears to diverge from different points offset by a distance D when viewed from those two orthogonal directions. Index-guided lasers 3905 dramatically reduce astigmatism, however, D=5 μm of uncorrected astigmatism is still commonly found in conventional index-guided lasers 3905, and this astigmatism varies with output power to limit performance. Performance limitations are particularly troublesome in optical disc data recording and high-resolution bar-code reading applications. However, less than 1 μm of astigmatism on a special bent waveguide laser has been reported when the fabrication involved two material regrowth steps and the index contrast Δn is still less than 0.1.

To make a small astigmatism laser diode, a waveguide with a sufficiently large change in the real part of the index is beneficial. A laser structure with a large index step further minimizes, or even eliminates the astigmatism issues.

In view of the well-known undesirable property of edge-emitting laser diodes with respect to asymmetric near-field optical mode and resulting elliptical far-field radiation patterns, the following example discusses methods to minimize such undesirable properties. As discussed in further detail below, an example high-index-contrast (HIC) ridge waveguide (RWG) structure fabricated by a self-aligned, deep etch plus non-selective wet oxidation process may be employed to achieve a high-efficiency, symmetric output beam laser by reducing the lateral dimension of the active stripe to a width comparable to the waveguide thickness of a large optical cavity laser structure. A high slope efficiency of greater than 1 W/A may be achieved due to the structural elimination of current spreading and the effective passivation of the etch-exposed bipolar active region by the high-quality wet thermal native oxide.

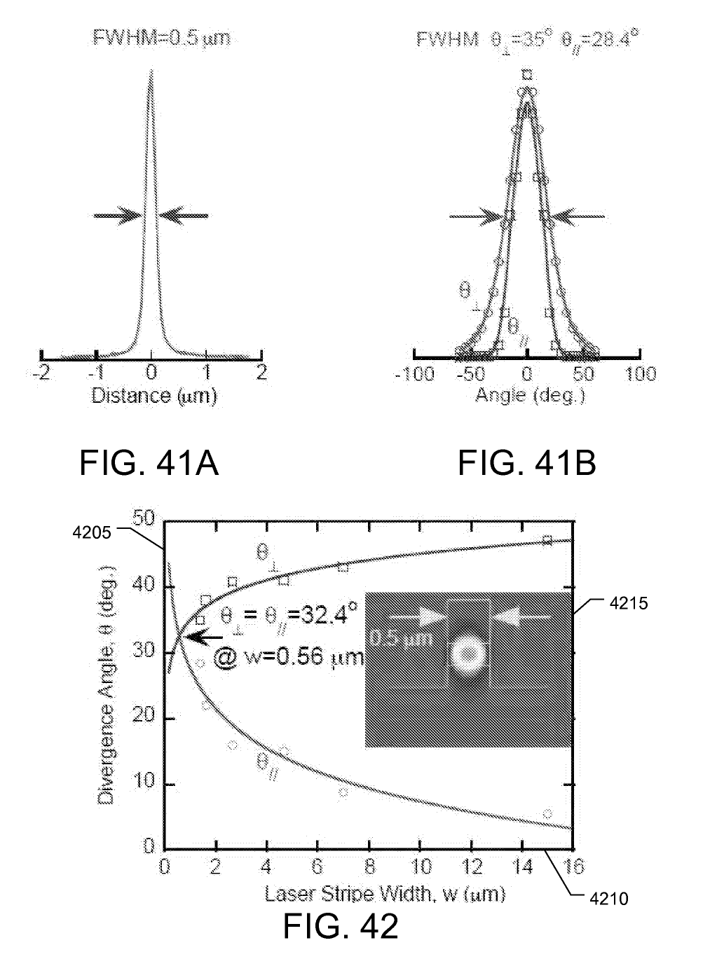

In the illustrated examples, HIC RWG laser diodes with different stripe width are fabricated in a manner similar to methods described above. In particular, an example fabrication process includes a λ˜808 nm high-power, large optical cavity, single InAlGaAs quantum well graded-index separate confinement heterostructure (GRINSCH) with Al_{0.6}Ga_{0.4}As waveguide cladding layers, grown via MOCVD. After deposition and patterning of a 200 nm thick PECVD SiNₓ mask layer, an example ridge is dry-etched via reactive ion etching (RIE) into a lower cladding layer and subsequently wet oxidized at 450° C. with the addition of 4000 ppm O₂ (relative to the N₂ carrier gas). Using an oxidation time of 20 min, approximately 250 nm of oxide is grown non-selectively on the entire RWG sidewall and base, resulting in an active region width w˜1.39 μm, as shown by the scanning electron microscope (SEM) cross-sectional image inset of FIG. 40. Leakage through the oxide layer is negligible (J<5 nA/cm²@2.5 V for an 184 nm oxide). Following oxidation, the SiNₓ mask may be selectively removed by RIE. After standard lapping, polishing, metallization and cleaving, unbonded devices may be probe tested, junction side up, under both pulsed (5 μS pulse, 1% duty cycle) and continuous wave (cw) conditions at 300 K using any suitable laser diode test system, such as the Keithley Model 2520 laser diode test system. Device facets are uncoated and near-field and far-field radiation patterns are characterized under cw bias, also on unbonded, p-side up devices. FIG. 40 shows a total (2 facet) output power 4005 vs. current 4010 characteristic for an example w=1.39 μm, L=1107.1 μm HIC RWG stripe geometry laser, showing a low threshold current of Iₜₕ=25.3 mA and a high differential responsivity of 1.02 W/A (differential quantum efficiency of η_{d}=68.0%) in cw mode (sweep time ˜1.34 sec) up to 100 mA (˜4×Iₜₕ). To avoid potential thermal damage, the unbonded device is not operated to higher cw current values, however the high slope efficiency is maintained under pulsed operation up to 9×Iₜₕ with no rollover. Such high slope efficiency is largely attributed to the total elimination of current spreading by the example deep-etched device structure, which leads to an excellent overlap of the optical mode and optical gain. FIG. 41A shows the near field image of the single-mode optical profile, tightly confined by the low-index thermal oxide and deep-etched ridge, with a FWHM of 0.5 μm and intensity of only 1.4% of the peak height at the oxide/semiconductor interface position.

FIG. 41B shows the far-field radiation profile at 150 mA cw, indicating divergence angles of approximately 35.0° and 28.4° in the fast and slow axes, respectively. The large slow axis divergence angle of 28.4° may result from the increased diffraction from the narrow laser stripe. FIG. 42 demonstrates the relationship of divergence angles 4205 with increasing laser stripe width 4210. As expected, an example slow axis divergence angle 4205 increases as an example laser stripe width 4210 decreases towards a submicron regime. An opposite trend of decreasing divergence angle 4205 with decreasing laser stripe width 4210 may be due to thermal lensing effects. The logarithmic fits to the measured data shown for both divergence angles reaches an intersection point at 32.4°, projecting that a perfectly circular output beam may be achievable from a diode laser with stripe width w=0.56 μm. An inset 4215 of FIG. 42 shows a beam propagation method (BPM) simulation for the same example wafer and device structure. The simulation leads to a slightly smaller laser stripe width of 0.5 μm to achieve a circular mode profile. Such a small discrepancy may be due to the passive nature of the BPM simulation which neglects carrier-dependent index variations present in the active devices. The projected submicron device dimension required for a circularly-symmetric output may still be realizable with optical-patterning of a larger masking stripe (thus avoiding more costly e-beam lithography processing) by using the scaling capability inherent in the lateral sidewall oxidation and careful time control. An important advantage of the non-selective oxidation step employed here may include the ability to both passivate surface defects and achieve substantial smoothing of the etched sidewall, which may be critical for enabling both efficient carrier recombination and low loss waveguiding in submicron-dimension active devices.

### Polarization

The total light output of a laser diode may be described as a combination of unpolarized spontaneous emission and well-polarized coherent light. QW semiconductor lasers commonly operate in the transverse electric (TE) mode, resulting from the anisotropy of the QW structure (i.e., the planar symmetry of electronic wavefunctions in a QW structure). Current uses of polarized laser diodes include applications employing polarizing beam splitters (PBSs) and diffractive optical structures. The TE polarization direction is defined in terms of electrical field parallel to the plane of incidence on a boundary between materials.

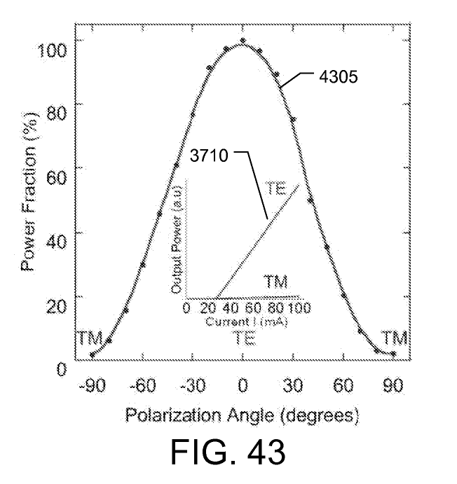

Characterization is quite simple: a broadband polarizing beam splitter cube (extinction ratio>1:1000, λ: 650-1000 nm) fixed on a rotatable polarization analyzer stage is set between the laser output facet and an optical power detector. The measurement starts with determining the maximum power (i.e., power output in TE polarization, defining a 0° analyzer angle) by rotating the beam splitter. FIG. 43 illustrates normalized power fraction curve 4305 for a native oxide-confined RWG laser with a 5 μm stripe width. An inset 4310 illustrates an LI curve of the laser diode. Power values are selected at I=100 mA. In the example plot 4305 of FIG. 43, the ratio of total power of a w=5 μm laser's output power at different polarization directions is compared against the peak TE polarized output power, normalized to a “power fraction” value with maximum of 100%. The inset 4310 presents a typical TE/TM LI plot of the measured laser which is operated under a pulsed mode with 1% duty cycle. Less than 2% power is TM polarized (i.e. perpendicular to QW plane), indicating a polarization ratio>1:50. Persons of ordinary skill in the art will appreciate that a polarization ratio on the order of 1:1000 can be achievable with an unstrained QW structure.

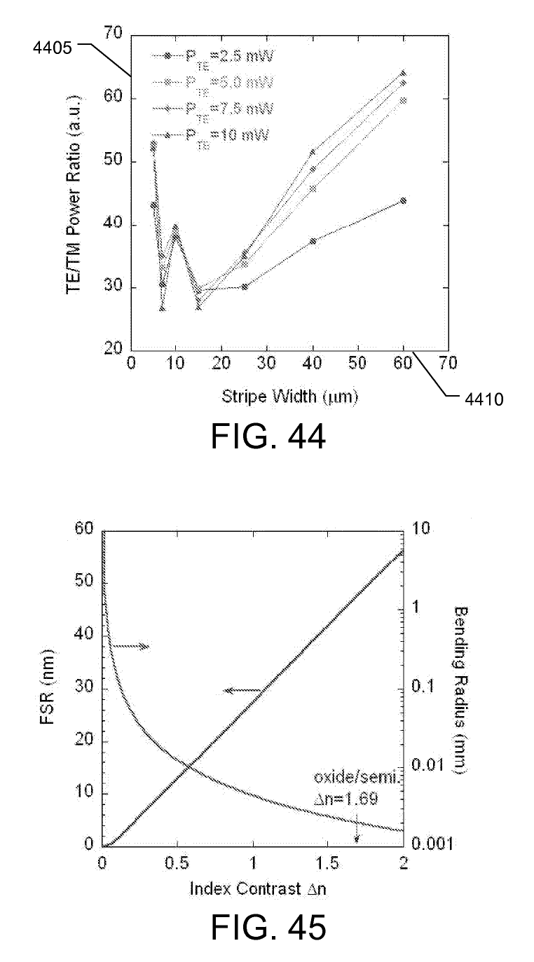

The polarization ratio at different power levels for lasers with varying stripe width is also studied. FIG. 44 illustrates curves for polarization ratio 4405 versus laser stripe width 4410 at various output power levels. As the stripe width increases from 15 μm to larger values, a clear rising trend of polarization ratio is noticed in FIG. 44, which is likely due to the increasing anisotropy of the QW structure (QW transverse dimension QW vertical thickness). However, note that in the narrow stripe region (7 μm, 5 μm) the polarization ratio is enhanced rapidly with decreasing of stripe width. One explanation for the above behavior is that the HIC waveguide birefringence may start playing an important role in significantly changing the TE and TM gain profiles because the effective index for the TE mode is much smaller than that for the TM mode for a single-mode HIC waveguide. However, such effective indicies are approximately same for a multimode waveguide. The curves in FIG. 44 reveal the same polarization change trend as a function of the laser stripe width for various power levels, which indicates that there is a weak dependence of the polarization change on the power. Furthermore, the measurement of polarization ratio may turn out to be a single method for determining the single-mode regime for HIC laser diodes.

### Semiconductor Ring Lasers

While semiconductor ring resonators have been explored for over three decades, rings with large free spectral range (FSR) and low loss have largely become a reality with the availability of HIC waveguides. FIG. 45 illustrates curves comparing a free spectral range 4505 and a bending radius 4510 versus an index contrast 4515. In the illustrated example of FIG. 45, a dependence is shown on the index contrast Δn of the FSR and of the bending radius that guarantee roughly 0.1 dB/rad of radiation losses. Additionally, the minimum bending radius varies roughly as Δn−1.5 and FSR=29Δn^{-1.5} (nm) for Δn≧0.1. For example, with a conventional low index contrast technology (Δn=0.01), the available FSR is only 6 GHz (0.17 nm), and the minimum bending radius is around 4-5 mm. However, for the native oxide/semiconductor index contrast of Δn=1.69, a ring resonator is capable of achieving an FSR of 0.021 GHz (47.5 nm), equal to 4762 channels in a 100 GHz spaced fiber-optic wavelength division multiplexing (WDM) system, with a bending radius of 2 μm. Hence, one of the goals of the systems, methods, and apparatus described herein is to utilize the HIC at an oxide/semiconductor interface, and take advantage of the smoothing effect during non-selective oxidation to ultimately achieve low loss, high finesse, sharply bent ring resonators.

Due to the challenge of building an output coupling waveguide suitably close (<1 μm) to the ring resonator to extract light out of the resonator cavity, half-ring lasers with a FP cavity have been first fabricated here by simply cleaving a race-track ring resonator into half. In the testing scheme used here, race-track ring resonators with bending radius values ranging from 10 to 320 μm are laid out on the mask design such that, when cleaved, the half-ring resonators on the same test bar all have the same total cavity length (as shown above in FIG. 21), thereby facilitating a fair comparison of threshold current among devices. This is achieved by adjusting the length of the straight sections to give each resonator the same total cavity length L=2πL+2L_{straight} and centering the devices so that, regardless of cleave position, each half-ring resonator has the same total length L=πL+2L_{straight}.

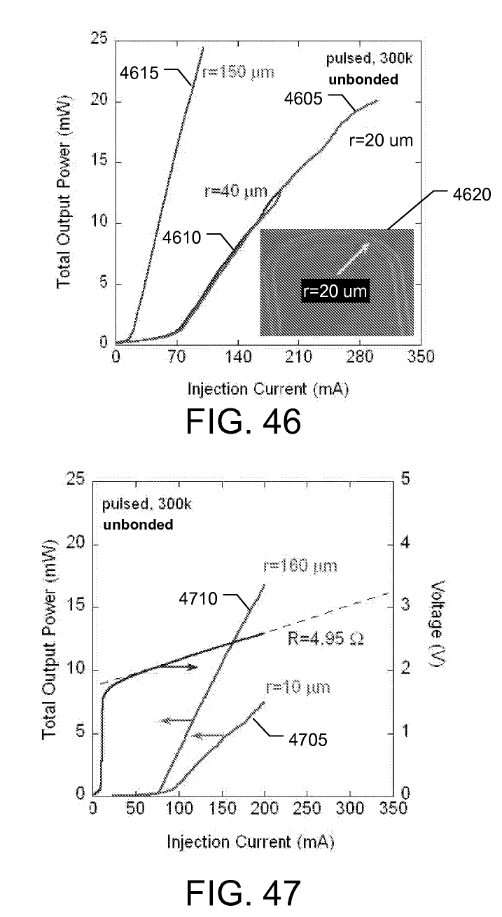

The LI characteristics of three native oxide-confined half-ring lasers are shown in FIG. 46. In the illustrated example, FIG. 46 includes a 10 μm laser 4605, a 40 μm laser 4610, and a 150 μm laser 4615, each of which are pulsed with a 0.05% duty cycle, unbonded, and include uncoated facets at 300° K. The lasers demonstrate low threshold currents of 16.6 mA, 62 mA and 65 mA for 4 μm wide lasers with curvatures of 150, 40 and 10 μm, respectively. An inset 4620 of FIG. 46 shows a top-view SEM image of another half-ring laser with r=20 μm.

FIG. 47 illustrates PECVD SiO₂-confined half-ring resonator lasers with radii of 10 μm (curve 4705) and 160 μm (curve 4710). For comparison purposes, the PECVD SiO₂-confined HIC half-ring resonator lasers with the same laser stripe width (w=4 μm) are fabricated by a conventional process flow discussed above. Higher threshold currents (Iₜₕ=86 mA and 75 mA) are needed to reach stimulated emission for the PECVD SiO₂-confined half-ring lasers with both small and large radii (r=10 and 160 μm, respectively). Furthermore, a comparison of the laser slope efficiency R_{d} for plots in FIGS. 46 and 47 reveal that all native oxide-confined half-ring lasers achieve a higher slope efficiency than PECVD SiO₂-confined devices. For example, R_{d}=0.12 W/A and 0.31 W/A are obtained for native oxide-confined half-ring lasers with r=10 and 150 μm, respectively. On the other hand R_{d}=0.07 W/A and 0.14 W/A are obtained for PECVD SiO₂-confined half-ring lasers with r=10 and 160 μm, respectively. A differential resistance of R=4.95 Ω is extracted from the IV curve for the PECVD SiO₂-confined half-ring laser (r=10 μm), comparable to the R=5.58 Ω result for a r=10 μm native oxide-confined half-ring laser (data not shown), indicating that the slightly smaller contact window resulting from the second lithography step in the conventional process flow (see FIG. 3) is not an important factor to impact SiO₂-confined device performance.

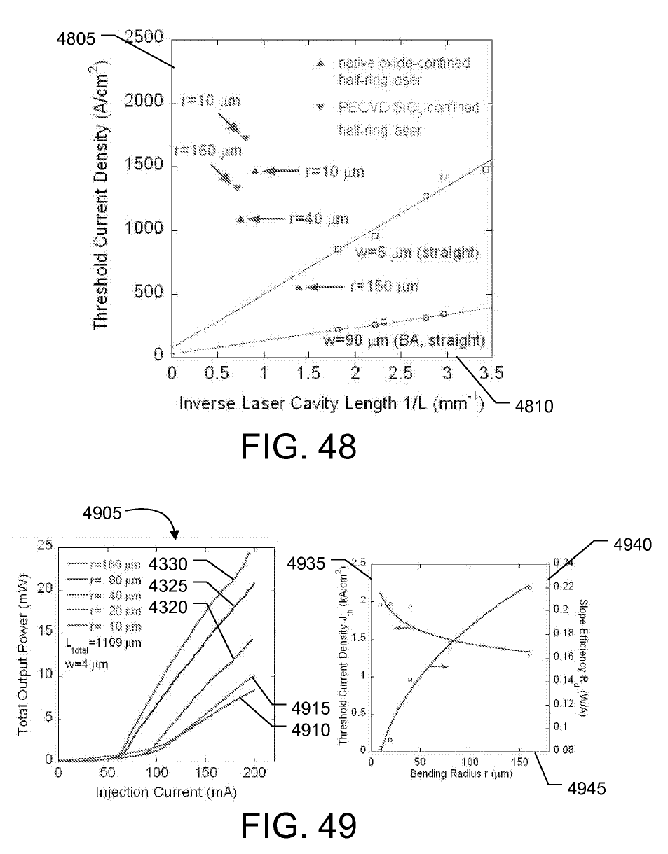

Taking the laser cavity length into account, the threshold current density values of the half-ring lasers in FIGS. 46 and 47 are compared in FIG. 48 to the reference straight device values (shown in FIGS. 25 and 26). FIG. 48 illustrates comparisons of inverse laser cavity length 4805 versus threshold current density 4810 for straight broad-area (w=90 μm) and narrow stripe (w=5 μm) lasers. Half ring lasers are shown with triangles having radii of 10, 40, and 150 μm. In the illustrated example of FIG. 48, the r=150 μm half-ring laser (Iₜₕ=16.6 mA, L=719 μm, w=4 μm) has a lower threshold current density of Jₜₕ=577 A/cm² than should a straight narrow stripe (w=5 μm) laser of the same cavity length, demonstrating an extremely low bend loss. Persons of ordinary skill in the art will appreciate that, to date, the smallest radius of curvature previously reported for high-index contrast curved resonator lasers was r=100 μm for a half-ring laser fabricated using an impurity-induced layer disordering plus oxidation process. FIG. 48 also illustrates a comparison of the results between Iₜₕ=62 mA for r=40 μm and Iₜₕ=65 mA for r=10 μm radius of curvature native oxide-confined half-ring resonators, normalized as Jₜₕ=1088 and 1465 A/cm². This is just 2.73× and 3.12× higher, respectively, than results projected for comparable length straight narrow stripe (w=5 μm) devices. The same comparison yields a 4.15× and 3.52× higher respective threshold current density for r=10 and 160 μm radii of curvature PECVD SiO₂-confined half-ring lasers. This is presumably because of a rough semiconductor/PECVD SiO₂ interface with a higher state density, leading to a high scattering loss and non-radiative recombination, respectively.

In order to study the bending and scattering loss by comparing the device lasing parameters (Iₜₕ, R_{d}), it is beneficial to find a single bar containing a series of lasers of different bending curvatures to eliminate the impact of cavity length-related mirror loss and processing-introduced discrepancies. FIG. 49 illustrates a plot 4905 of LI characteristics for native oxide-confined half-ring lasers on the same bar (w=4 μm, L=1109 μm) having radii of r=10 (curve 4910), 20 (curve 4915), 40 (curve 4920), 80 (curve 4925), and 160 μm (curve 4930). FIG. 49 also illustrates a comparison of threshold current density 4935 and slope efficiency 4940 with bending radii 4945 for the aforementioned lasers (i.e., 4910, 4915, 4920, 4925, and 4930). The plot 4905 of FIG. 49 illustrates a trend that to achieve simulated emission with a more sharply bent devices, a higher threshold current is required (and thus, due to the same cavity area, a higher threshold current density). This simultaneously shows a trend of lower slope efficiencies. Note that an overall low slope efficiency for all the half-ring lasers in FIG. 49, compared to straight narrow stripe lasers whose slope efficiency is usually>0.9 W/A, is attributed to coupling of power to higher bend-loss higher-order waveguide modes in the curved sections of the resonator.

There is also additional scattering loss due to non-optimal contact lithography, which is suspected to contribute to this behavior. FIG. 50 illustrates a microscope image (magnification=800) of PR half-ring patterns 5005, 5010. The half-ring pattern 5005 shows an abnormally large line-edge roughness 5015, appearing only along the curved part and leading to additional sidewall roughness of curved RWGs after dry etching. The smooth line edge obtained for the straight section largely eliminates the possibilities of any over/under-exposure or PR chemical molecules-related erosion problems. Accordingly, the most likely cause the interference of UV light wave fronts (often existing in contact photolithography) are parallel to straight parts, but have an angle up to 90 degrees to the curved part. The larger the angle, the more negative the influence of the interference can be, which is consistent with the situation observed in FIG. 50. More careful photolithographic processing, plus the use of other line-edge reduction steps, such as an optimized O₂ descum and post-bake, may offer additional advantages.

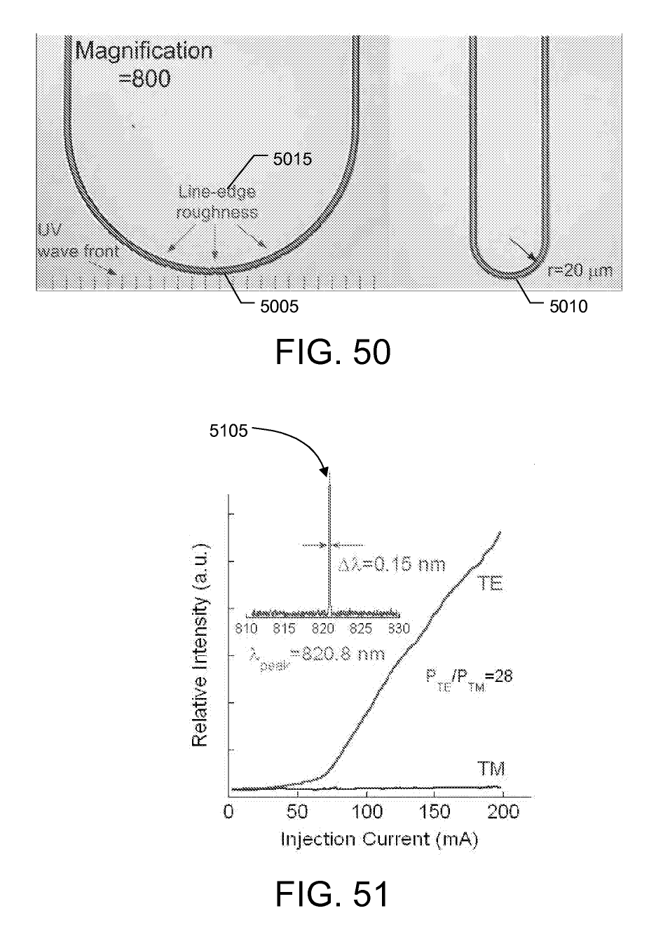

FIG. 51 illustrates polarization-dependent LI characteristics of a native oxide-confined half ring laser with a radius of 320 μm. In the illustrated example of FIG. 51, a half-ring laser with a stripe width of 4 μm and a bend radius of 320 μm demonstrates a TE-preferred stimulated emission, though the TE/TM power ratio is only 28 (˜2×lower than that of a slightly wider (w=5 μm) straight laser (PTE/PTM=53)). The greater impact of sidewall roughness on the performance of the curved devices due to the issue discussed above can severely degrade the gain for the TE mode but have little effect on the TM mode which has not reached stimulated emission. As a result, the power ratio of TE and TM modes presented here should not be taken to indicate that the polarization ratio is dependent on laser geometry.

Shown in an inset 5105 of FIG. 51, the laser spectrum is also measured for a CW operation of an unbonded device. The lasing peak wavelength at I=150 mA (2.5×Iₜₕ) is 820.8 nm with a line width of 0.15 nm, both higher than that of a straight laser in FIG. 31, primarily because of a higher injection current, resulting in a higher laser cavity temperature and consequently leading to a bigger spectral red shift and line width broadening.

Another example includes a single-facet folded-cavity half-racetrack ring resonator diode laser with a folding bend radius as low as r=10 μm. Although the wet thermal oxidation of AlₓGa₁₋ₓAs in H₂O vapor has typically been limited to high-Al-content alloys (0.85≦x≦1) due to the high Al selectivity of the oxidation rate, the oxidation smoothing described above in which the controlled addition of trace amounts of O₂ to the N₂+H₂O process gas [<7000 ppm (0.7%) O₂ relative to N₂] enables the practical, relatively nonselective oxidation of the low Al content AlₓGa₁₋ₓAs alloys (0≦x<0.85) common in AlGaAs edge-emitting laser heterostructures. Such high quality of this example nonselective wet thermal oxide is evident from its higher refractive index (indicating a higher density), greater etch resistance, and its ability to provide sufficient surface passivation of a deep etch-exposed bipolar active region to minimize non-radiative recombination. Accordingly, an excellent continuous wave 300K performance HIC RWG electrical injection lasers results.

Example straight and half-ring HIC RWG laser diodes are fabricated in a λ=808 nm high-power, large optical cavity, single strained InAlGaAs quantum well graded-index separate confinement heterostructure (GRINSCH) with Al_{0.6}Ga_{0.4}As waveguide cladding layers, grown via metalorganic chemical vapor deposition. After a 200 nm thick silicon nitride (SiNₓ) masking layer is grown by plasma enhanced chemical vapor deposition (PECVD) and optically patterned, the waveguide ridge is deeply dry-etched via reactive ion etching (RIE) with a BCl₃/Cl₂/Ar chemistry into an example lower cladding layer yielding vertical sidewalls of well controlled ridge dimension. The example etch mask is a w˜5 μm wide stripe patterned in racetrack-shaped rings of different end curvatures to form example devices which are ultimately cleaved normal. Such example rings form a convenient curved-resonator test structure for indirect assessment of bend losses through laser device characteristics.

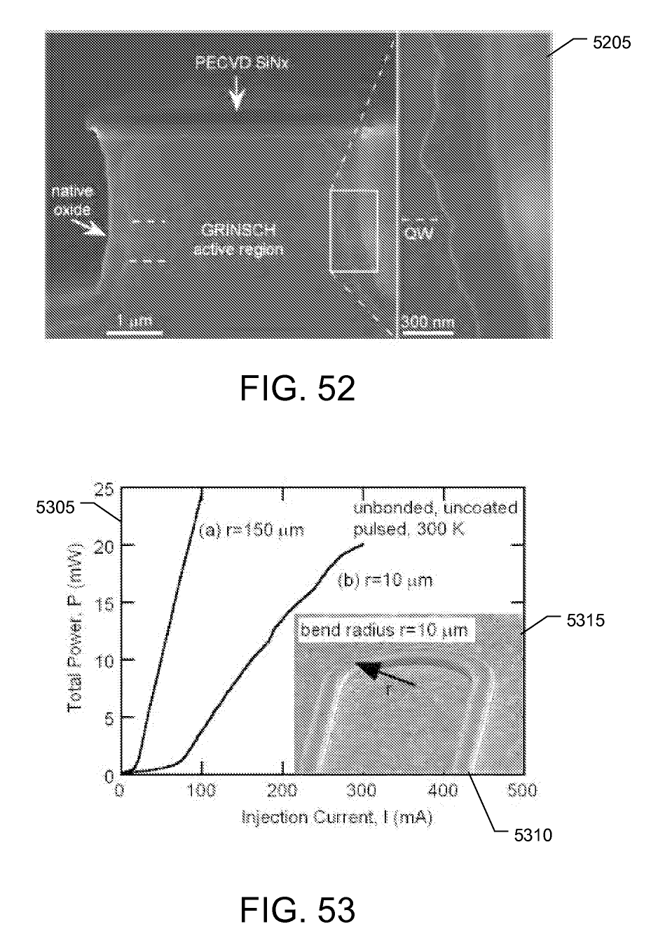

After etching, the example SiNₓ-masked AlGaAs heterostructure ridge is nonselectively oxidized at 450° C. in water vapor with the addition of 4000 ppm O₂ (relative to N2 carrier gas flow rate). Using an oxidation time of 30 min, approximately 340 nm of amorphous oxide is grown on the RWG sidewall and base. FIG. 52 shows a scanning electron microscope (SEM) cross-sectional image of the example HIC RWG before SiNₓ etch mask removal, and indicates a final active region width of w˜3.9 μm. A higher magnification inset 5205 to FIG. 52 shows that the nonselective oxidation depth is quite uniform even though the alloy composition varies widely across the example GRINSCH graded AlₓGa₁₋ₓAs layers (0.35<x<0.6) and sandwiched InAlGaAs quantum well. The native oxide is sufficiently insulates such that narrow-stripe lasers may be formed by direct p-contact metallization after selectively removing the SiNₓ mask by RIE with a CF₄/O₂ plasma, thereby enabling a self aligned process requiring no additional insulation or lithography. A negligible leakage of JL<4.2 nA/cm2@2.5 V has been measured for a ˜140 nm oxide of Al_{0.3}Ga_{0.7}As grown under similar conditions (450° C., 28 min, 2000 ppm O₂; data not shown).

Much like other example samples described above, after standard lapping, polishing, metallization, and cleaving procedures, unbonded devices may be probe tested (junction-side up) at 300 K under pulsed conditions (0.5-2 μS pulses, 0.05-5% duty cycle) using a Keithley Model 2520 pulsed laser diode test system. Device facets are uncoated and FIG. 53 shows the total output power 5305 (from 1 facet due to the folded cavity geometry) vs. current 5310 characteristic for HIC RWG half-racetrack-ring lasers with bend radii of (a) r=150 μm and (b) r=10 μm, showing low threshold currents of Iₜₕ=16.6 mA and 65 mA, respectively. The corresponding slope efficiencies for these example devices (measured at 2×Iₜₕ) are 0.305 W/A and 0.105 W/A, respectively. The bend radius is measured hereto the center of the example waveguide ridge. An inset 5315 to FIG. 53 shows an SEM top view image of a representative r=10 μm radius device after metallization.

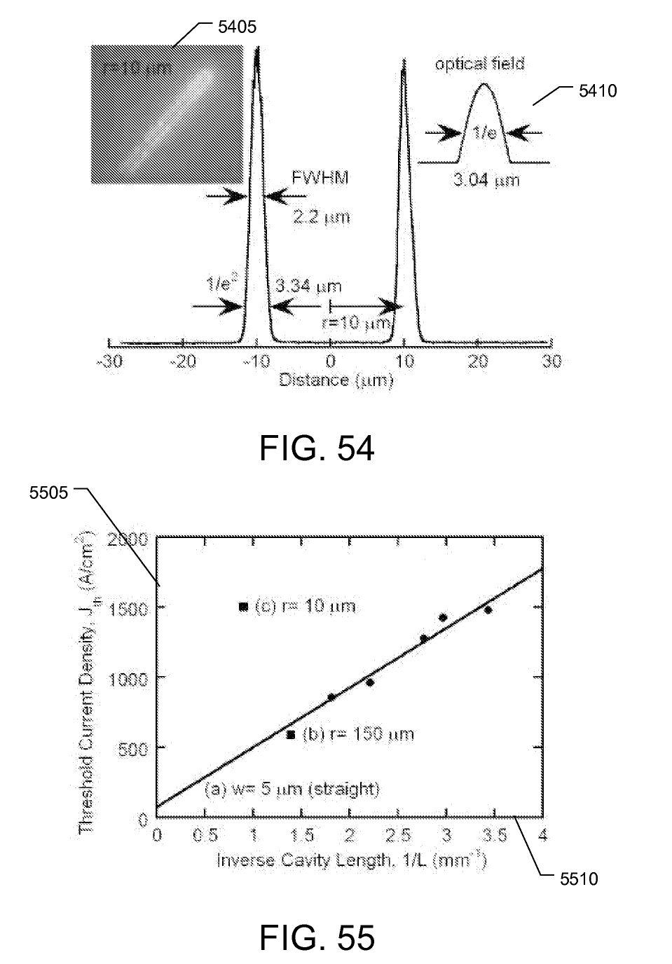

The near-field (NF) profile of an example r=10 μm radius laser is shown in FIG. 54, measured at 250 mA in pulsed mode (2 μS pulse width, 5% duty cycle). An optical photograph in a left inset 5405 of FIG. 54 shows a typical r=10 μm device while lasing. The example NF profile shows two intensity peaks separated by exactly 10 μm, demonstrating operation of the half-racetrack geometry laser with both resonator end mirrors emitting in the same direction from a single cleaved facet. Each peak has a full width at half maximum (FWHM) of 2.2 μm, and 98% of the output power is emitted from within the two w=3.9 μm apertures, demonstrating the tight lateral confinement provided by the example HIC structure. Mode simulations indicate that at a width of 3.9 μm, this example HIC RWG structure is capable of supporting 7 modes, with a cut-off width for single-mode operation of 0.86 μm. With the lithographically-determined NF peak spacing providing accurate scale calibration, the measured NF intensity (E2) profile 1/e2 full width of 3.34 μm is only slightly larger than the simulated E-field 1/e full width of the lowest-order (m=0) mode, 3.04 μm (shown in an inset 5410 on the right of FIG. 54), and less than the simulated 1/e full widths of 3.54, 3.64, 3.74, 3.78, 3.84 and 3.90 μm for the m=1 through m=6 higher order modes, respectively.

For comparison of straight and curved cavity laser results, threshold current density Jₜₕ 5505 vs. inverse cavity length 1/L 5510 data are plotted in FIG. 55 for (a) similarly processed w=5 μm narrow stripe straight lasers along with Jₜₕ values for (b) the r=150 μm and (c) the r=10 μm example half-racetrack-ring lasers shown in FIG. 53. FIG. 55 shows that the r=150 μm device (Iₜₕ=16.6 mA, L=719 μm) has a value of Jₜₕ=592 A/cm², which is very comparable to equivalent-length straight lasers. However, the r=10 μm device (Iₜₕ=65 mA, L=1109 μm) Jₜₕ=1503 A/cm² is just 3.34× higher. The near field images and simulations discussed above indicate that the output from the laser straight waveguide sections is predominantly in the m=0 mode, and the similar thresholds of straight and r=150 μm curved devices suggests that the bend loss for this mode is negligible for r=150 μm devices. In contrast, the comparatively low 0.305 W/A slope efficiency of the r=150 μm device, 3.9 times lower than observed on equivalent length straight lasers (1.18 W/A, data not shown), may be explained by the loss of power above threshold from higher order modes which have greater radiation loss and are excited by the m=0 lasing mode as it enters the curved resonator section. The high efficiency of straight lasers fabricated via this process suggests that non-radiative recombination at the grown oxide/semiconductor interface is negligible.

Interface passivation is at least one factor affecting semiconductor device performance, particularly for GaAs-based devices with high surface recombination velocity. With the dimension shrinkage of devices, the increasing surface-to-volume ratio may further degrade the device performance. Seeking an effective method to passivate the surface states and decrease the surface recombination velocity has been a major research area for III-V compound semiconductor electronic and optoelectronic/photonic devices for more than two decades. For the HIC native oxide-confined RWG lasers described herein, the direct contact of the native oxide formed in the non-selective oxidation with the active region can be severely problematic if the non-selective oxide cannot effectively passivate the interface.

The passivation capability of the non-selective oxides is first explored by studying the threshold current density and efficiency of lasers with varying stripe width. Similar deep-etched lasers passivated by PECVD SiO₂ with similar thickness (˜150 nm) and refractive index (˜1.7) to the native oxide are also fabricated in a conventional process flow (see FIG. 3) for comparison purpose.

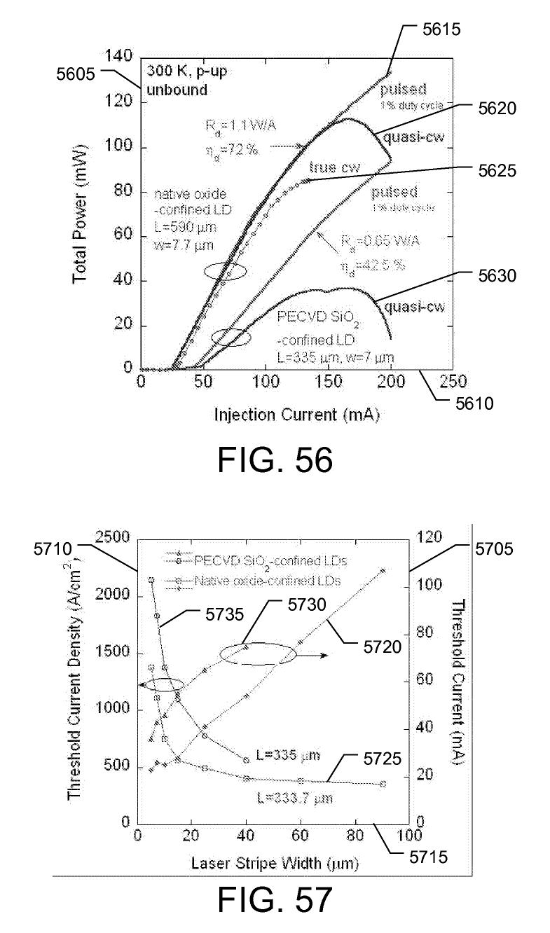

FIG. 56 illustrates curves for a total output power 5605 as a function of injection current 5610 for a pulsed laser 5615, a quasi-CW laser 5620, and true-CW native oxide-confined laser 5625. Additionally, the example curves of FIG. 56 illustrate a PECVD SiO₂ quasi-CW laser 5630. The laser performance of narrow stripe (w˜7 μm) lasers passivated by the native oxide are shown to be much better than PECVD SiO₂-passivated devices. As discussed above, a laser diode with a short cavity usually demonstrates a higher slope efficiency due to a higher distributed mirror loss. Such a laser also requires less current to reach population inversion (i.e., stimulated emission) than a laser with a longer cavity because of a smaller cavity volume. As a result, if the PECVD SiO₂ had a better or comparable passivation capacity relative to the native oxide, a PECVD SiO₂-confined, 335 μm long laser should have a higher slope efficiency and a lower threshold current than a native oxide-confined laser with a cavity length of 590 μm. However, the PECVD SiO₂-confined laser needs a higher threshold current (Iₜₕ=40 mA) and exhibits a lower slope efficiency (R_{d}=0.65 W/A) when compared with a threshold current of 24 mA and a slope efficiency of 1.1 W/A achieved on a native-oxide confined laser under a pulsed operation (1% duty cycle). This indicates that the widely used PECVD SiO₂ is not as good as the non-selective native oxide in passivating surface states.

Without any heat sink, when both laser types are measured under “quasi-CW” conditions (e.g., a fast dc current sweep time of ˜0.34 sec), the native oxide-confined laser can still start lasing at low threshold current and follow the pulsed LI curve without rolling over until I˜160 mA. In contrast, during quasi-CW operation the PECVD SiO₂-confined laser experiences a higher threshold and lower efficiency with a “rollover” of output (usually associated with heat) at I˜120 mA. Accordingly, this suggests a poorer thermal performance of PECVD SiO₂-confined devices.

A stripe width-dependent study is shown in FIG. 57, in which the threshold current 5705 and corresponding current density 5710 of native oxide-confined and PECVD SiO₂-confined lasers (with nearly identical structure dimension) are plotted as a function of the laser stripe width 5715. As the laser stripe width 5715 decreases, lasing threshold current densities 5710 increase rapidly, but at different rates for both laser types. Native oxide-confined lasers 5720, 5725 clearly demonstrate a smaller increase than PECVD SiO₂-oxidized lasers 5730, 5735, especially in the narrow stripe range (w<10 μm). For a native oxide-confined laser, the threshold current density at w=5 μm is only 978 A/cm² (3.4×) higher than that of a laser with w=40 μm. On the other hand, for a w=5 μm PECVD SiO₂-confined device, the value of 1590 A/cm² is 3.8× higher than at w=40 μm. An overall higher threshold current density of PECVD SiO₂-confined lasers further proves a poorer interface passivation from the deposited dielectric.

Low non-radiative recombination can also be reflected by a high internal quantum efficiency, defined as the ratio of radiative electron-hole recombination rate to total (radiative+non-radiative) recombination rate. The internal quantum efficiency η₁ is not a directly measurable parameter, but is correlated with the slope efficiency R_{d} and related to external differential quantum efficiency η_{d} through the relationship in Equation 16.

$$\frac{1}{{η}_{d}} = \frac{1}{{η}_{i}} [ 1 + \frac{2 {α}_{i} L}{ln ( \frac{1}{{R}_{1} {R}_{2}} )} ] \qquad Equation 16$$

In equation 16, αᵢ represents the laser total internal loss, L is the cavity length, and R₁ and R₂ are the facet reflectances. As shown in FIG. 48, when plotting 1/η_{d} versus

$$\frac{2 L}{ln ( 1 / {R}_{1} {R}_{2} )}$$

see plot 4805), the internal quantum efficiency and internal loss can be obtained by extrapolating the external differential quantum efficiency to the point of zero cavity length (L=0). Additionally, the internal loss can be found from the slope through equation 16. The native oxide-confined lasers with stripe width of 5 (curve 5810), 7 (curve 5815), 10 (curve 5820) and 90 μm (curve 5825) (BA) all achieve an internal quantum efficiency higher than 80%, which indicates that the non-radiative recombination at the ridge sidewall does not cause a large performance penalty although narrow stripe lasers do exhibit some degradation in efficiency.

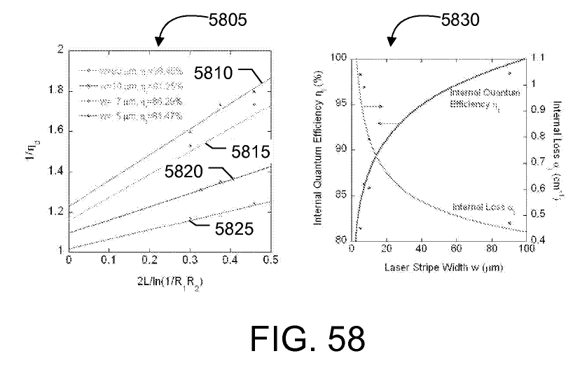

The interface electrical quality is also associated with the interface roughness since a rough surface is a seedbed for defects. The total internal loss as a function of laser stripe width, shown as a plot 5830 of FIG. 58, illustrates a similar relationship to that theoretically described above. That is, the narrower the waveguide width, the higher the scattering loss due to the increasing interaction of the light propagation with sidewall roughness. Though the laser total loss is not only composed of waveguide scattering loss but also material absorption losses which are usually several orders of magnitude higher than waveguide scattering loss, a very low total loss value of less than 1.1 cm⁻¹ for a narrow stripe native oxide-confined laser is consistent with a low scattering loss from a smooth interface achieved through the oxidation smoothing mechanism described above.

### Passivation

Persons of ordinary skill in the art have found that the formation of antistructural defects of the type involving the transfer of As to a Ga sublattice site (AsGa), and conversely the transfer of Ga to an As sublattice site, is thermodynamically favorable in GaAs. They exist around the middle of the bandgap and strongly pin the Fermi level, becoming the dominant defects for a native oxide covered GaAs surface. It is also well-known that As-oxides (˜80% As₂O₃, 20% AS₂O₅) in the AlGaAs (or GaAs) thermal oxide are thermodynamically unstable and tend to undergo the chemical reaction below even at room temperature (see Equation 17, below).

As₂O₃+2GaAs→4As+Ga₂O₃ Equation 17

The extra As released from this reaction generates more defect states at the semiconductor/oxide interface, pinning the Fermi level. Therefore, the effectiveness of interface passivation is related to either the removal of As or decreasing the ratio of As₂O₃ in the oxide. The excellent performance (especially the high internal quantum efficiency) of lasers fabricated by the methods described herein, in which the oxide is in direct contact with the bipolar active region point where electrons and holes recombine to emit photons) demonstrates that these non-selectively grown oxides (formed by O₂-enhanced wet thermal oxidation) have a low density of interfacial defects and are, thus, particularly well suited for electrically passivating the sidewall in deep etched HIC RWG laser structures. The conversion of RIE etch-damaged semiconductor material close to the etched surface to a high quality, low defect amorphous native oxide is also beneficial for improving optoelectronic device performance.

Hydrogenation has been a successful technique to lower the surface density states by converting As and “doped” hydrogen ions into volatile AsH₃ and effectively remove the AsGa defects. Compared with other surface treatment solutions which usually involve a complete removal of the native oxide from the semiconductor surface, this technique is more attractive due to its reliable electronic and chemical passivation. Furthermore, GaAs MOSFETs with Al₂O₃ as the gate insulator have been demonstrated with good device performance after hydrogenation treatment, which unambiguously shows that hydrogen ions can penetrate through the oxide layer, reaching the semiconductor and reducing the surface states.

Researchers recently reported a MOSFET whose device performance was enhanced by an intentional thermal oxidation process followed by additional annealing and PECVD SiNₓ deposition steps to drive the chemical reaction (Equation 17) towards the right side, leading to As diffusion from the semiconductor/oxide interface into the SiNₓ layer. As soon as As₂O₃ is completely converted to As, which quickly diffuses away in a high temperature ambient, only stable Ga₂O₃ is left, yielding improved device performance. Similar techniques could be applied to further improve the electrical quality of the already excellent non-selective AlGaAs native oxide/semiconductor interface.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. A method to reduce waveguide scattering loss, comprising:
forming a waveguide having a sidewall, the waveguide comprising a group III-V compound semiconductor material; and
growing a native oxide on the waveguide to form an index of refraction contrast at the sidewall, the native oxide grown in a controlled Oxygen-enriched water vapor environment to reduce a roughness of the sidewall.

2. A method as defined in claim 1, wherein the group III-V compound semiconductor comprises at least one of AlGaAs, GaAs, InGaAsN, or GaAsP.

3. A method as defined in claim 1, wherein the waveguide is at least one of a rib waveguide or a ridge waveguide.

4. A method as defined in claim 1, wherein the index of refraction contrast is at least greater than or equal to 1.

5. A method as defined in claim 1, further comprising adjusting an Aluminum ratio of the group III-V compound semiconductor material to affect an oxidation rate selectivity of the native oxide to control an oxide growth profile.

6. A method as defined in claim 1, wherein growing the native oxide comprises wet thermal oxidation.

7. A method as defined in claim 6, further comprising adjusting at least one of a plurality of oxidation parameters, the oxidation parameters comprising at least one of an oxidation temperature, an oxidation oxygen ambient concentration, an oxidation duration, a nitrogen flow rate, or a water vapor flow rate.

8. A method as defined in claim 7, wherein the oxidation oxygen concentration is at least 2000 parts-per-million (ppm) relative to the flow rate of Nitrogen used as a carrier gas for the water vapor.

9. A method as defined in claim 7, further including adjusting the at least one of the plurality of oxidation parameters to maximize an oxidation efficiency.

10. A method as defined in claim 1, further comprising growing the native oxide on an etched active region, the native oxide growth removing etch damage.

11. A laser, comprising:
a group III-V compound semiconductor waveguide, the waveguide having a core;
a native oxide grown on the waveguide in a controlled Oxygen-enriched water vapor environment; and
a sidewall interface between the waveguide core and the native oxide, the sidewall interface forming a high-index contrast and the sidewall interface comprising a root-mean-square (RMS) roughness less than 5 nano-meters (nm).

12. A laser as defined in claim 11, wherein the group III-V compound comprises at least one of AlGaAs, GaAs, InGaAsN, or GaAsP.

13. A laser as defined in claim 12, wherein the AlGaAs compound comprises an Aluminum ratio of x and a Gallium ratio of 1−x.

14. A laser as defined in claim 13, wherein x is between 0 and approximately 0.8.

15. A laser as defined in claim 11, wherein the laser comprises at least one of a graded index separate-confinement heterostructure (GRINSCH) ridge waveguide (RWG) laser, a double heterostructure laser, or a quantum well heterostructure.

16. A laser as defined in claim 15, wherein the GRINSCH RWG laser comprises at least one of a straight Fabry-Perot (FP) resonance cavity, or a curved resonance cavity.

17. A laser as defined in claim 16, wherein the curved resonance cavity is at least one of a half-ring FP resonance cavity, or a full ring resonator cavity.

18. A laser as defined in claim 17, wherein the full ring resonator cavity comprises at least one of a circular shape, a racetrack shape, or a closed-loop circulating shape.

19. A laser as defined in claim 16, wherein a radius of at least a portion of the curved resonance cavity is between 5 micro-meters and 150 micro-meters.

20. A laser as defined in claim 11, wherein the high-index contrast is between 1.0 and 1.7.

21. A laser as defined in claim 11, further comprising a bipolar active region operatively connected with the waveguide core, the active region providing simultaneous electrical passivation at an interface of the native oxide and waveguide core.

22. A laser as defined in claim 11, wherein the laser comprises an array of laser stripes.

23. A method of forming an optical waveguide, comprising:
forming a waveguide stripe on an AlGaAs substrate, the waveguide stripe having an active layer, a lower surface adjacent to a lower cladding, and an upper surface adjacent to an upper cladding;
etching the upper cladding, the waveguide stripe, and the lower cladding to form a ridge, the ridge having sidewalls; and
oxidizing the ridge in a controlled Oxygen-enriched water vapor environment to grow a native oxide on the sidewalls of the ridge.

24. A method of forming an optical waveguide as defined in claim 23, wherein the controlled Oxygen-enriched water vapor environment comprises an Oxygen concentration between 2000 and 7000 parts-per-million relative to the flow rate of Nitrogen used as a carrier gas for the water vapor.

25. A method of forming an optical waveguide as defined in claim 24, wherein the oxidizing is maintained for a time period between 7 and 60 minutes.

26. A method of forming an optical waveguide as defined in claim 23, further comprising controlling an Aluminum ratio of the AlGaAs substrate to affect an oxidation rate selectivity of the native oxide to control an oxide growth profile.

27. A method of forming an optical waveguide as defined in claim 26, wherein the Aluminum composition is between 0% and 60%.

28. A method of forming an optical waveguide as defined in claim 23, further comprising deposition of metal contacts to a p-type and n-type semiconductor to form a laser diode.

29. A method of forming an optical waveguide as defined in claim 23, further comprising forming a passive ring resonator.
